(19) United States
(12) Patent Application Publication
(10) Pub. No.: US 2011/0172815 A1
(43) Pub. Date: Jul. 14, 2011

(54) MEDICINE MANAGEMENT APPARATUS AND METHOD, BIN FOR THE APPARATUS, AND CART FOR THE APPARATUS

(75) Inventor: Jun Ho Kim, Daegu (KR)

(73) Assignee: JVM CO., LTD., Daegu (KR)

(21) Appl. No.: 12/987,899

(22) Filed: Jan. 10, 2011

(30) Foreign Application Priority Data
Jan. 11, 2010 (KR) 10-2010-0002353
Jul. 15, 2010 (KR) 10-2010-0068340
Jul. 27, 2010 (KR) 10-2010-0072299
Sep. 2, 2010 (KR) 10-2010-0086050

(51) Int. Cl. A47B 81/00; A47B 96/00; A47B 96/02; G06F 17/00; B65D 83/04; B65G 59/00; H05K 5/00; A47F 3/04

(52) U.S. Cl. 700/235; 312/209; 700/231; 221/92; 361/679.01; 62/251

(57) ABSTRACT

The present disclosure provides medicine management apparatuses that stores various kinds of medicines and permits the stored medicines to be dispensed according to prescriptions. More particularly, the present disclosure provides medicine management apparatuses that ensure stable medicine management and security while providing efficiency in stock management and preparation of medicines. The medicine management apparatus includes a plurality of shelves rotatably coupled to a vertically disposed circular rotary carousel and a plurality of bins seated on the shelves and accommodating medicines. The apparatus further includes a main door that opens and closes an inlet/outlet port formed at a front side of a housing of the medicine management apparatus; and a shelf assistant door that opens or closes an opened front part of each of the shelves exposed through the inlet/outlet port and is provided with a lock.

### CROSS-REFERENCE TO RELATED APPLICATION

This application claims the benefit under 35 U.S.C. §119 of Korean Patent Application No. 10-2010-0002353, filed on Jan. 11, 2010, Korean Patent Application No. 10-2010-0068340, filed on Jul. 15, 2010, Korean Patent Application No. 10-2010-0072299, filed on Jul. 27, 2010 & Korean Patent Application No. 10-2010-0086050, filed on Sep. 2, 2010, in the Korean Intellectual Property Office, the entireties of which are incorporated herein by reference.

### BACKGROUND

1. Technical Field

The present disclosure relates to a medicine management method and apparatus that stores various kinds of medicines and permits the stored medicines to be dispensed according to prescriptions. More particularly, the present disclosure relates to a medicine management method and apparatus that ensures stable medicine management and security while providing efficiency in stock management and preparation of medicines. The present disclosure also relates to a bin for the apparatus and a cart for the apparatus.

2. Description of the Related Art

In drugstores or hospitals, a variety of medicines are administered to patients. Furthermore, in accordance with advances in the pharmaceutical industry, new drugs appear every year, leading to an increase in the number or kind of medicines dispensed by pharmacists. As a result, management of medicines has become too complex to be carried out by manual operation, leading to the introduction of automated stock management systems.

For preparation of a combination of tablets or pills, an integrated preparation apparatus has been developed and used in the art to automatically prepare a dose of medicine according to a prescription. On the other hand, some medicines are difficult to package due to the size or shape thereof. Such medicines are generally packed in rectangular parallelepiped shaped paper bags or are provided as a solution in a bottle or plastic bag, so that the medicine packages have various shapes according to a packaging method.

As such, the uneven package size of the packaged medicines makes it difficult to receive or deliver the packaged medicines using an automated system. Furthermore, a conventional automatic dispensing system employs a robotic system for recognition, holding, and transportation of the packaged medicines, thereby requiring high installation costs.

A semi-automated dispensing system has been suggested in consideration of ease of inventory count and medicine dispense while reducing manufacturing costs. For example, U.S. Pat. No. 4,643,495, entitled “Mechanical Storage Cabinet with Container Conveyor”, describes a cabinet which comprises two endless chains disposed at opposite sides of the cabinet and rotated by a drive motor, and a plurality of shelves disposed inside the chains to face each other to achieve effective use of a space for stacking articles. In the present invention, the bottoms of the shelves are always directed downwards by a hinge structure coupled to the chains when the shelves are rotated, thereby preventing medicines from falling off of the shelves. The supporting structure for the chains and shelves is obtained by modifying U.S. Pat. No. 4,877,121, entitled “Vertical Excursion Accommodation Apparatus”, and allows the shelves to be stably secured to the chains by support arms and to be moved along an ellipsoidal trajectory extending in a vertical direction.

U.S. Pat. No. 5,438,523, entitled “Apparatus for storing and delivering sale units”, describes a plurality of bins, which are boxes for sorting and storing articles in a shelf U.S. Pat. No. 6,814,255, entitled “Method for controlling a drug dispensing system”, describes a management program for storing and dispensing medicines.

Since different medicines such as narcotics are subject to different levels of regulatory control, certified personnel must be in charge of dispensing such medicines. Further, different sizes of medicine packages require different installation sizes, which can be obtained through division of a space on the shelf, different installation heights or the like. However, this feature cannot be satisfied by techniques presently available in the art.

Furthermore, since the bin for receiving medicine in a shelf has a predetermined storage capacity, it is difficult to efficiently cope with the case where the medicine has a large volume or when the number of medicines is increased. Accordingly, it is necessary for the bin to have a variable storage capacity according to the volume or number of medicines to be stored therein. Further, in the case where the bin is partially occupied by a small volume and small number of medicines, it is desirable that an inner space of the bin be divided such that two or more types of medicine can be stored therein.

Although numerous studies have focused on development of a medicine management system that can store a number of medicines while allowing a desired medicine to be dispensed as needed, delivery of the dispensed medicine to a patient is still manually carried out in the art, so that the dispensed medicine can be mixed with medicine intended for other patients or can be delivered to the wrong patient, possibly resulting in drug related injury. Therefore, there is a need for a system that allows a medicine dispensed from the medicine management system to be accurately delivered to a patient.

### BRIEF SUMMARY

The present disclosure is directed to solving the problems of the related art as described above, and an embodiment of the present disclosure provides a medicine management apparatus that ensures stability and security in medicine management through classification according to levels of regulatory control.

Other embodiments of the present disclosure provide a bin for receiving medicine and a medicine management apparatus including the same. The bin permits easy increase or decrease of spaces for receiving medicines by disposing an elongated case on an upper end of an outer perimeter wall thereof or by disposing a partition therein.

Still other embodiments of the present disclosure provide a medicine management apparatus and method. The medicine management apparatus enables more rapid and easier management of medicines by allowing medicines prepared according to prescriptions to be dispensed according to the kind of medicine rather than according to patients and sorting the dispensed medicines in a cart having a plurality of compartments.

Still other embodiments of the present disclosure provide a cart and a medicine management method using the same. In the method, medicines prepared according to prescriptions are dispensed according to the kind of medicine rather than according to patients and are then sorted in the cart having a plurality of compartments, so that the medicines dispensed from a medicine depository are prevented from being mixed with other medicines and can be accurately delivered to a patient.

In accordance with one aspect, a medicine management apparatus includes a plurality of shelves movably coupled to a vertically disposed rotatable circular carousel and a plurality of bins seated on the shelves and accommodating medicines. The apparatus further includes a main door that opens or closes an inlet/outlet port at a front side of a housing of the medicine management apparatus; and a shelf assistant door that opens or closes a front part of each of the shelves exposed through the inlet/outlet port and is provided with a lock.

In accordance with another aspect, a bin for a medicine management apparatus for placing and managing medicines on a plurality of shelves includes a box-shaped body open at an upper side thereof; and an elongated case detachably coupled to an upper end of the body to increase the height of the bin.

In accordance with a further aspect, a medicine management apparatus for placing and managing medicines on a plurality of shelves includes the plurality of shelves movably coupled to a vertically disposed rotatable circular carousel, and a plurality of bins seated on the shelves and having a box-shaped body open at an upper side thereof to accommodate medicines therein, each of the bins including an elongated case detachably coupled to an upper end of a box-shaped body open at an upper side thereof to increase the height of the bin.

In accordance with yet another aspect, a medicine management method for dispensing medicine from a medicine management apparatus for placing and managing medicines on a plurality of shelves includes: resorting medicine information of prescription data having information of medicines to be dispensed, according to the kind of medicine; dispensing the medicines from corresponding shelves according to the re-sorted medicine information, and sorting and dispensing the dispensed medicines according to patients.

In accordance with yet another aspect, a medicine management apparatus that places and manages medicines on a plurality of shelves is provided. The apparatus includes a cart having a plurality of compartments partitioned from each other to sort and discharge medicines, which have been dispensed according to the kind of medicine from the shelves, according to patients.

In accordance with yet another aspect, a medicine management method for dispensing and delivering medicines from a medicine depository to patients includes: aligning medicine information of prescription data having information of medicines to be dispensed, according to the kind of medicine and patients; dispensing the medicines of the medicine information aligned according to the kind of medicine from the medicine depository; and inputting the dispensed medicines into a cart having a plurality of compartments.

In accordance with yet another aspect, a cart for dispensing and delivering medicines from a medicine depository to patients includes a plurality of compartments that accommodate medicines, which are managed to be delivered to patients by the medicine management method, according to the patients.

### BRIEF DESCRIPTION OF THE DRAWINGS

FIG. 1 is a perspective view of a medicine management apparatus according to an embodiment of the present disclosure;

FIG. 2 is a side view of the medicine management apparatus according to the embodiment of the present disclosure;

FIG. 3 is an exploded view of a height adjustor of the medicine management apparatus according to the embodiment of the present disclosure;

FIG. 4 is a front view of the height adjustor of FIG. 3;

FIG. 5 illustrates another example of the height adjustor;

FIG. 6 is a perspective view of a shelf assistant door and a shelf of the medicine management apparatus according to the embodiment of the present disclosure;

FIG. 7 is a cross-sectional view of the shelf assistant door of FIG. 6;

FIG. 8 is a partially enlarged view of a surveillance sensor of the medicine management apparatus according to the embodiment of the present disclosure;

FIG. 9 is a schematic front view of a refrigerating unit of the medicine management apparatus according to the embodiment of the present disclosure;

FIG. 10 is a front view of partitioned spaces on the shelf of the medicine management apparatus according to the embodiment of the present disclosure;

FIG. 11 is a perspective view of a bin for a medicine management apparatus according to a first embodiment of the present disclosure;

FIG. 12 is a bottom view of the bin of FIG. 11;

FIG. 13 is a perspective view of a modification of the bin of FIG. 11;

FIG. 14 is a side sectional view of a drawer structure of the bin of FIG. 11;

FIG. 15 is a perspective view of the bin of FIG. 11 in use;

FIG. 16 illustrates operation of a shelf and a bin according to another embodiment of the present disclosure;

FIG. 17 is a flowchart of a process of stocking medicines initially according to an embodiment of the present disclosure;

FIG. 18 is a flowchart of a process of stocking medicines according to an embodiment of the present disclosure;

FIG. 19 is a flowchart of a process of dispensing medicines according to an embodiment of the present disclosure;

FIG. 20 is a perspective view of a bin for a medicine management apparatus according to a second embodiment of the present disclosure;

FIG. 21A is a plan view of a body of the bin of FIG. 20;

FIG. 21B is a side sectional view of the body of the bin of FIG. 20;

FIG. 22A is a plan view of an elongated case of the bin of FIG. 20;

FIG. 22B is a side sectional view of the elongated case of the bin of FIG. 20;

FIG. 22C is a side view of the elongated case of the bin of FIG. 20;

FIG. 22D is a bottom view of the elongated case of the bin of FIG. 20;

FIG. 23 is a view of a partition of the bin of FIG. 20;

FIG. 24 is a flowchart of a medicine management method according to an embodiment of the present disclosure;

FIG. 25 is a flowchart of a management method for comparison with the medicine management method of FIG. 24;

FIG. 26 illustrates exemplary tables of prescription information used in the medicine management method according to an embodiment of the present disclosure;

FIG. 27 is a conceptual view of the medicine management apparatus according to the embodiment of the present disclosure;

FIG. 28 is a flowchart of a medicine management method using a cart; and

FIG. 29 to FIG. 36 illustrate various modifications of the cart.

### DETAILED DESCRIPTION

Hereinafter, exemplary embodiments of the present disclosure will be described in detail with reference to the accompanying drawings.

According to an embodiment, a medicine management apparatus 100 includes a plurality of shelves 200 movably coupled to a vertically disposed rotatable circular carousel 1 and a plurality of bins 300 receiving medicines and seated on the shelves.

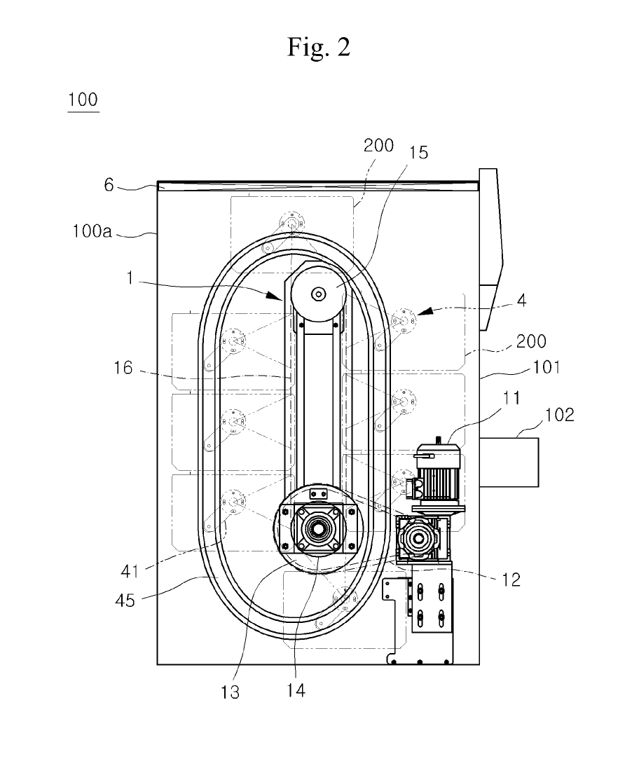

As shown in FIG. 2, the rotatable circular carousel 1 is disposed inside a housing 100a and includes a drive unit for moving the shelves 200 upwards or downwards. The rotatable circular carousel 1 may be provided only to one side of the medicine management apparatus 100. Advantageously, the rotatable circular carousel 1 may be provided to either side inside the housing 100a in consideration of the weight of the shelves 200 which store the medicines.

The rotatable circular carousel 1 includes a lower stage gear 13, a lower drive gear 14 integrally connected to and rotated by the lower stage gear 13, an upper drive gear 15 disposed at an upper side inside the housing 100a, a chain 16 wound around outer circumferential surfaces of the upper and lower drive gears, and a plurality of height adjustors 4 separated at regular intervals from each other and secured to the chain 16 while being coupled to side surfaces of the shelves 200. Here, the lower stage gear 13 receives a rotational force from a drive motor 11, direction and speed of which are controlled by a controller (not shown), through a power transmission means 12 such as chains.

During rotation of the drive motor 11, the lower stage gear 13 and the lower drive gear 14 are integrally rotated to move the height adjustors 4 secured to the chain 16, so that the shelves 200 are endlessly rotated.

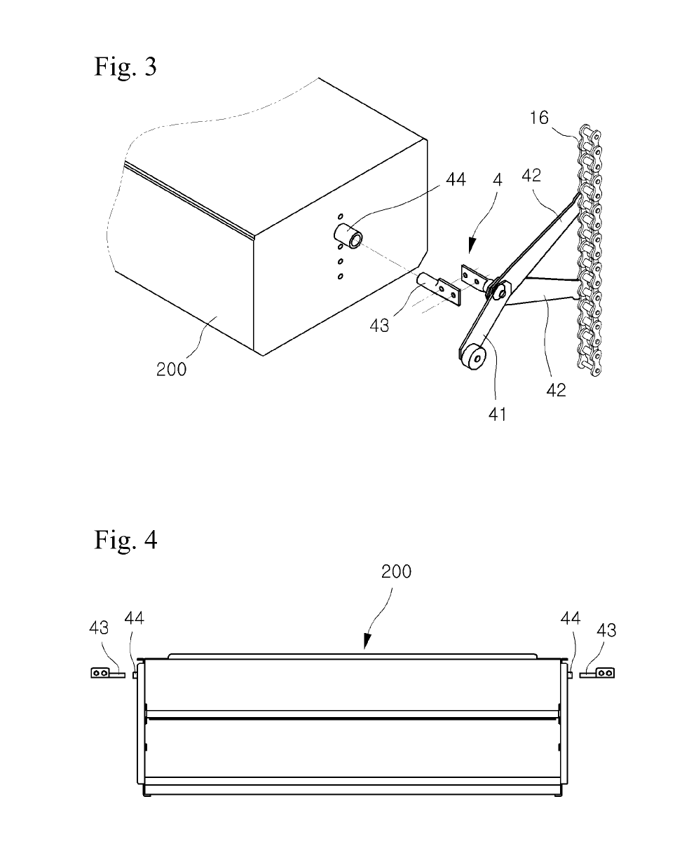

Referring to FIG. 3, the height adjustor 4 may be provided with a link arm 41 for track restriction to allow stable movement of the shelf 200 such that a distal end of the link arm 41 can be caught by an ellipsoidal movement track groove 45 formed on a side surface of the housing 100a. Detailed configuration and operation of the rotatable circular carousel 1 are described in U.S. Pat. No. 4,643,495, entitled “Mechanical storage cabinet with container carousel”, and U.S. Pat. No. 4,877,121, entitled “Vertical excursion accommodation apparatus”.

Operation of the rotatable circular carousel 1 is primarily controlled by the controller. The controller operates the rotatable circular carousel 1 to allow a user to recognize a position of a certain bin while allowing the bin to remain flush with an inlet/outlet port 101 formed on a front side of the housing 100a.

The apparatus further includes an operation panel (not shown) to allow a user to directly operate the rotatable circular carousel independently of the operation of the rotatable circular carousel by the controller. In the event where the controller is not properly operated, the operation panel can operate the rotatable circular carousel and ensures operation of the medicine management apparatus 100 in the case of accidents, such as failure of the controller.

FIG. 3 illustrates one of height adjustors shown in FIG. 2.

For ease of manufacture, the height adjustors 4 are separated at regular intervals from each other and secured to the chain 16. A distance between adjacent shelves is adjusted for effective storage of medicines according to the size of medicine package. In this case, the distance between the shelves secured to a pair of rotatable circular carousels facing each other may be adjusted by the height adjustors 4.

Specifically, when the top of a medicine package situated on a certain shelf reaches the bottom of an adjacent shelf positioned thereabove, the height of the adjacent shelf can be lowered to enable the tall medicine package to be received on the certain shelf. Further, when a space between the top of two layers of medicine packages in a certain shelf and a lower surface of an adjacent shelf above the certain shelf is large, the certain shelf is raised to reduce the space, thereby improving space utilization.

Accordingly, as shown in FIGS. 3 and 4, the height adjustor 4 includes a pair of support arms 42 forming a triangular support structure on the chain 16 of the rotatable circular carousel 1, and support members 43 extending from distal ends of the support arms 42 to face each other. Further, the height adjustor includes a hinge receptor 44 that is disposed at either sidewall of the shelf 200 to be adjustable in height and receives the support member 43 while allowing rotation of the support member 43.

The pair of support arms 42 constitutes a triangular shape to reduce transfer of vibration of the chain 16 to the shelf 200 while stably transferring a place of the shelf 200 to the chain 16. The support arms 42 meet each other at the distal ends thereof, from which the support members 43 extend towards the shelf 200 and are inserted into the hinge receptor 44 formed on the shelf 200, so that the shelf 200 is caught by the height adjustor 4 to swing forwards or rearwards.

The hinge receptor 44 is bolted to the sidewall of the shelf 200 and may be adjusted in height. For this purpose, a plurality of holes is formed at different heights through the opposite sidewalls of the shelf 200 such that a user can select an installation height of the hinge receptor 44.

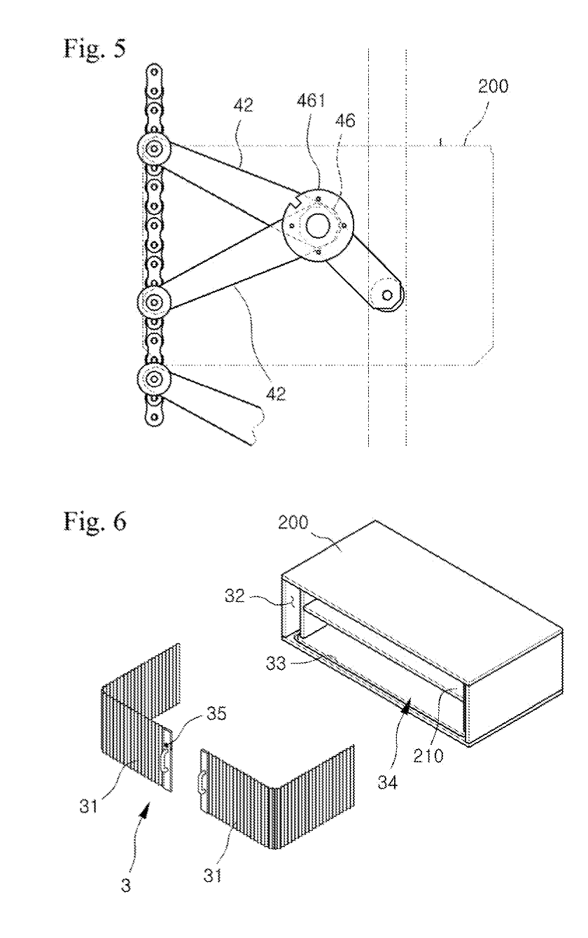

FIG. 5 illustrates a height adjustor according to another embodiment. In this embodiment, the height adjustor includes a rotary connector 46 that is supported on the distal ends of the support arms 42 through a bearing to rotate freely thereon and includes a disc 461, to which the side surface of the shelf 200 is secured at various positions of the disc 461 by bolts.

The secured position of the hinge receptor 44 on the side surface of the shelf 200 or the position of the side surface of the shelf bolted to the rotary connector 46 may be on a vertical line passing through the center of gravity of the shelf 200 to allow the shelf 200 to remain horizontal without being slanted. For example, the hinge receptor 44 may be positioned above the center of gravity on the vertical line passing through the center of gravity to prevent the shelf from being turned downwards. Accordingly, the adjustable range of the height of the shelf is half the total height of the shelf.

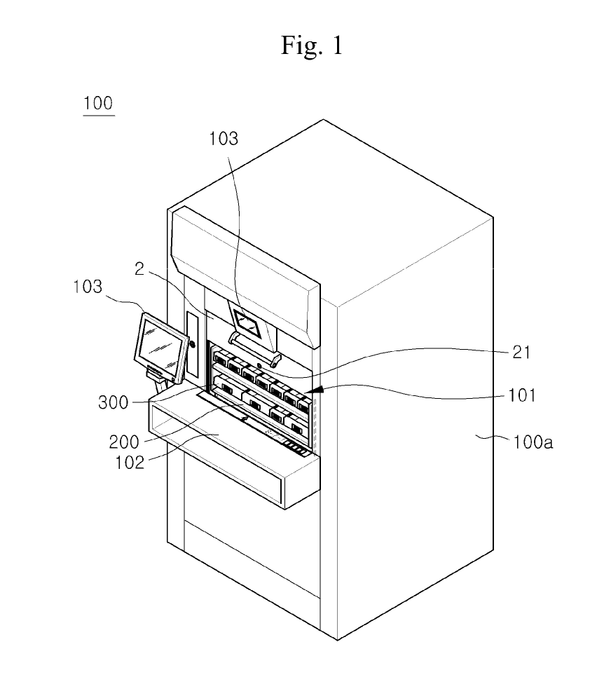

Referring again to FIGS. 1 and 2, the rotatable circular carousel 1 and the shelves 200 are mounted inside the housing 100a and medicines received in the shelves 200 are received into or dispensed from the housing 100a through the inlet/outlet port 101 formed on the front side of the housing 100a. For convenience in receiving or dispensing the medicines, a rack 102 is disposed at the bottom of the inlet/outlet port 101 and input/output units 103 are located at one side of the rack 102 and an upper end of the inlet/outlet port 101 to input various pieces of information related to stocking or dispensing the medicines. Further, the apparatus is provided with databases for storing receipt/dispense history of medicines, processing stored information, and making suggestions to the user based upon the processed information, as well as the controller.

The inlet/outlet port 101 is provided with a main door 2 to open or close the inlet/outlet port 101 to prevent unauthorized access to medicine. The main door 2 is a sliding door which is slid in the vertical direction, and is provided with a lock 21 that locks the main door 2 when closing the inlet/outlet port 2.

The lock 21 may be an electronic lock configured to unlock the main door 2 upon receiving an ID and password of a user through the input/output units or may be a mechanical lock composed of a key and padlock. As such, the main door may be realized in various ways including a hinged door.

The main door 2 completely prevents unauthorized access to any medicine received in the medicine management apparatus. As a result, the main door 2 prevents unauthorized persons from rearranging medicine, thereby preventing medicine from being incorrectly dispensed.

In order to allow only qualified persons to approach or manage special medicines such as drugs while allowing an authorized user to approach and manage other typical medicines, the apparatus may further include a shelf assistant door as an individual lock for a shelf that stores a medicine subject to special regulations.

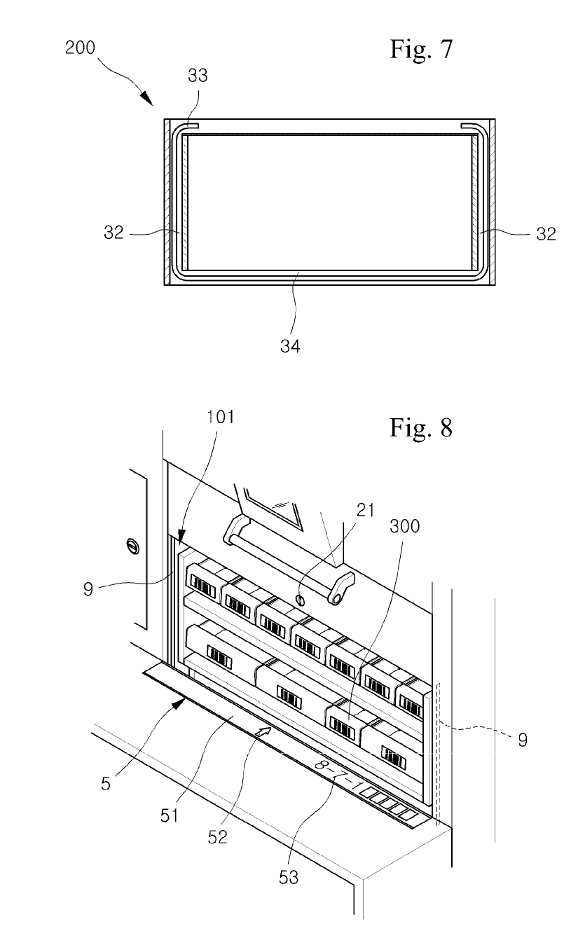

As shown in FIGS. 6 and 7, for a certain shelf for storing a medicine subject to special regulations, the shelf assistant door 3 may be composed of a pair of crease screens 31, which can be received in receiving slits 32 formed at both sides of the shelf 200 to open a front part 34 of the shelf and can be moved along a transfer groove 33 formed on the bottom or ceiling at the front part of the shelf 200 to close the front part 34 of the shelf 200.

The shelf 200 for storing a particular medicine has a box shape and is closed at all sides thereof except for the front part 34. The crease screens 31 are spread out along the transfer groove 33 to close the front part 34.

The receiving slits 32 are formed at both sides of the shelf such that the pair of crease screens 31 can be slidably received in the receiving slits 32 to open or close the front part 34 of the shelf. The transfer groove 33 is formed along an edge of the shelf 200 to extend along the bottom or ceiling of the front part 34 and the receiving slits 32 such that the crease screens 31 can completely open the front part 34 of the shelf when a user opens the crease screens 31.

Further, when the crease screens 31 are spread out to close the front part 34 of the shelf, the shelf assistant door 3 can be locked using a door lock 35 disposed at a portion where the crease screens 31 meet each other. As in the lock of the main door, the door lock 35 may be realized in various ways such as an electronic lock or a mechanical lock.

As such, the shelf assistant door 3 is configured to permit only a qualified user to release the lock and close the shelf assistant door after dispensing a particular medicine from the associated shelf, thereby preventing unqualified persons from gaining access to the particular medicine.

Referring to FIG. 8, to prevent erroneous operations of the main door and the shelf by a user when stocking or dispensing medicines, surveillance sensors 9 are disposed inside the inlet/outlet port 101 to detect an obstacle present in the inlet/outlet port and the controller prevents operation of the rotatable circular carousel 1 or a closing operation of the main door 2 when the surveillance sensors 9 detect the obstacle.

The surveillance sensors 9 are disposed to face each other inside the inlet/outlet port 101, specifically, immediately inside slits along which main door 2 is raised or lowered. Each of the surveillance sensors 9 may be a laser sensor that includes a laser emitter and a laser receiver to detect an article located between the laser emitter and the laser receiver through emission and detection of laser beams. Thus, when a user pulls a bin from the shelf such that the bin is partially located on the shelf, the user can be informed from the surveillance sensors 9 of that the bin is partially located on the inlet/outlet port.

Upon receiving a signal from the surveillance sensors indicating that an obstacle is present at the inlet/outlet port, the controller interrupts power supply to the drive motor and locks the door despite instructions for operation of the rotatable circular carousel, thereby preventing injury to a user or damage to the bin due to operation of the rotatable circular carousel or the main door. Furthermore, after receiving the signal indicating the presence of an obstacle from the surveillance sensors, the controller outputs an alarm message or sound to the input/output units to inform a user of the presence of the obstacle upon receiving instructions for operation of the rotatable circular carousel or the main door from the user.

Since the shelf may be provided with a plurality of bins for storing medicines, it is difficult for a user to easily recognize a position of a certain bin that stores a medicine stocked by the user or a medicine to be dispensed. Thus, the apparatus may further include a display unit 5 that displays a position of a medicine stocked into a certain bin or a position of the bin through the input/output units 103 (see FIG. 1).

The display device 5 may be configured to display an approximate position of a bin, which is searched for by a user, using a serial number of a shelf receiving the bin and a front image of the shelf through monitors of the input/output units 103. Alternatively, in order to inform a user of a more accurate position of the bin searched for by the user, the display device 5 may be longitudinally disposed on the inlet/outlet port 101 to display an image directly indicating the position of the bin 300.

FIG. 8 also illustrates a dot display monitor 51 longitudinally disposed along the inlet/outlet port 101 on the rack 102 located on the bottom of the inlet/outlet port 101. The dot-type display monitor 51 is configured to display brief information 53 relating to a serial number of the bin searched for by a user, an acronym of a medicine searched for by a user, and the number of medicines to be dispensed while displaying the position of the bin using an arrow 52 according to a method described below.

Upon receiving information indicating a certain bin or the name of a certain medicine searched for by a user through the input/output units 103, the controller rotates the rotatable circular carousel to move a shelf storing the certain bin to the inlet/outlet port and the display unit 5 displays the position of the bin using an arrow, whereby the user can conveniently find the desired medicine or bin.

Referring to FIG. 2, the housing 100a may be provided with a temperature/humidity regulator 6 for regulating the temperature and humidity therein. The temperature/humidity regulator 6 has a well-known structure that includes a temperature controller with an air conditioner and a humidity controller with a dehumidifier, and a detailed description thereof will be omitted herein. The temperature/humidity regulator may be, for example, a blower for discharging hot air to the outside of the housing.

The temperature/humidity regulator 6 is controlled by the controller and regulates the temperature and humidity of the interior of the housing. Frequent use of the rotatable circular carousel 1 causes an increase in the inner temperature of the housing 100a, and temperature and humidity at which medicine is stored may deviate from ideal temperatures as indicated by a manufacturer due to seasonal climate variation or the installation location of the management apparatus. In particular, since liquid medicine can be spoiled according to temperatures even in an expiration date thereof, it is necessary for the liquid medicine to be stored at a suitable temperature. The temperature/humidity regulator 6 ensures that medicine remains good up to an expiration date thereof.

The temperature/humidity regulator 6 may be provided with a temperature recorder which records variation in the internal temperature of the housing. The temperature recorder records variation in the internal temperature of the housing during an operating period, identifies a time zone where the internal temperature of the housing deviates from a preset range, and informs a user of the variation in the internal temperature through the input/output units. With this structure, it is possible to prevent a medicine, which is not stored at a proper temperature, from being provided to consumers by allowing a user to refer to a record of variation in the internal temperature when dispensing the medicine, such as a liquid medicine, which is sensitive to storage temperature.

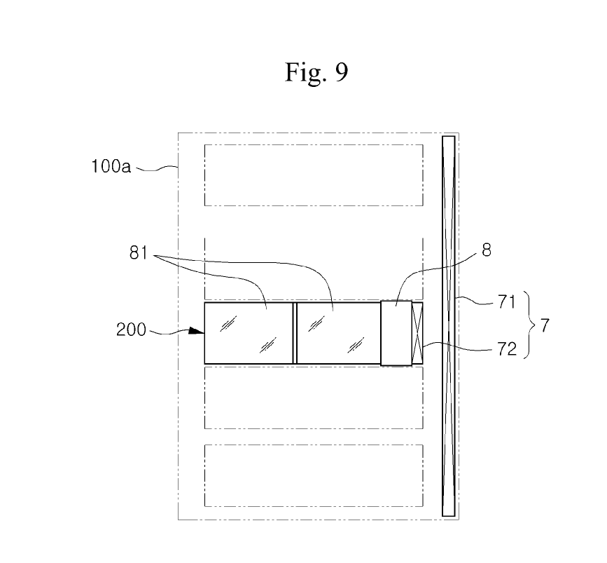

On the other hand, some special medicines such as injectables require refrigeration at temperatures lower than room temperature. Thus, as shown in FIG. 9, one of the shelves may be provided with a refrigerating unit 8, which receives power from the housing 100a via a wireless power supply unit 7, to store such special medicines at lower temperatures.

The refrigerating unit 8 may be a typical refrigerating apparatus which is operated by electric power. More advantageously, the refrigerating unit 8 is composed of a thermoelectric element which has a simple and small structure and requires little power.

The wireless power supply unit 7 uses a magnetic field to supply power to the refrigerating unit, and may include a wireless power supply 71, which is composed of a coil disposed at one sidewall of the housing, and a wireless power receiver 72, which is disposed on an inner wall of the shelf 200 facing the one sidewall of the housing and moving parallel to the sidewall of the housing. With this configuration, it is possible to use the shelf storing special medicine as a refrigeration shelf by means of the refrigerating unit while supplying consistent power. It should be noted that the shelf 200 including the refrigerating unit 8 is provided with a lagging material and a door 81 capable of opening or closing a front side of the shelf 200. Alternatively, when the refrigerating unit 8 is composed of the thermoelectric element which requires little power, it is possible to provide a simple structure and reduce installation costs using a battery.

In this case, the medicine management apparatus is capable of storing special medicines such as injectables, which require refrigeration, thereby diversifying the variety of medicines that can be stored in the medicine management apparatus. In addition, the temperature/humidity regulator may prevent heat generated from the refrigerating unit from affecting other medicines stored in other shelves.

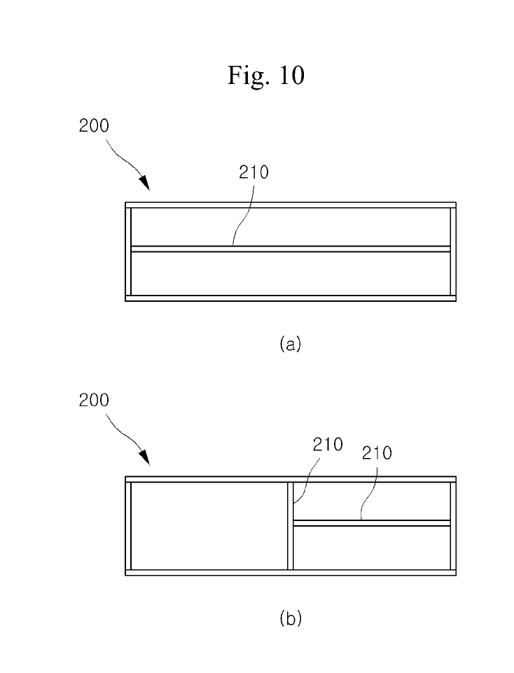

As shown in FIG. 6 or 10, to achieve effective use of an inner space of the shelf 200, the shelf 200 may be further provided with a horizontal intermediate plate 210 which divides the inner space of the shelf 200. In order to store a small amount of medicine having a small size in each compartment, the horizontal intermediate plate 210 is provided to the shelf 200 and divides the inner space of the shelf 200 into upper and lower compartments such that the bins can be stacked in the upper and lower compartments. The shelf 200 may further include a vertical intermediate plate 210 which vertically divides the interior thereof to store large bins and small bins at the same time.

When the shelf 200 includes the horizontal intermediate plate 210, the rotatable circular carousel 1 is controlled in consideration of the height of the intermediate plate 210. Specifically, when the controller controls the rotatable circular carousel 1 to provide a bin 300 located on the intermediate plate 210 to a user, the rotatable circular carousel 1 is controlled to allow the bottom of the intermediate plate 210 to be located on the bottom of the inlet/outlet port.

In this case, when dispensing prepared medicines, a user can collectively dispose the medicines in a single shelf or in a small number of adjacent shelves, so that the medicines can be rapidly dispensed through minimized operation of the carousel.

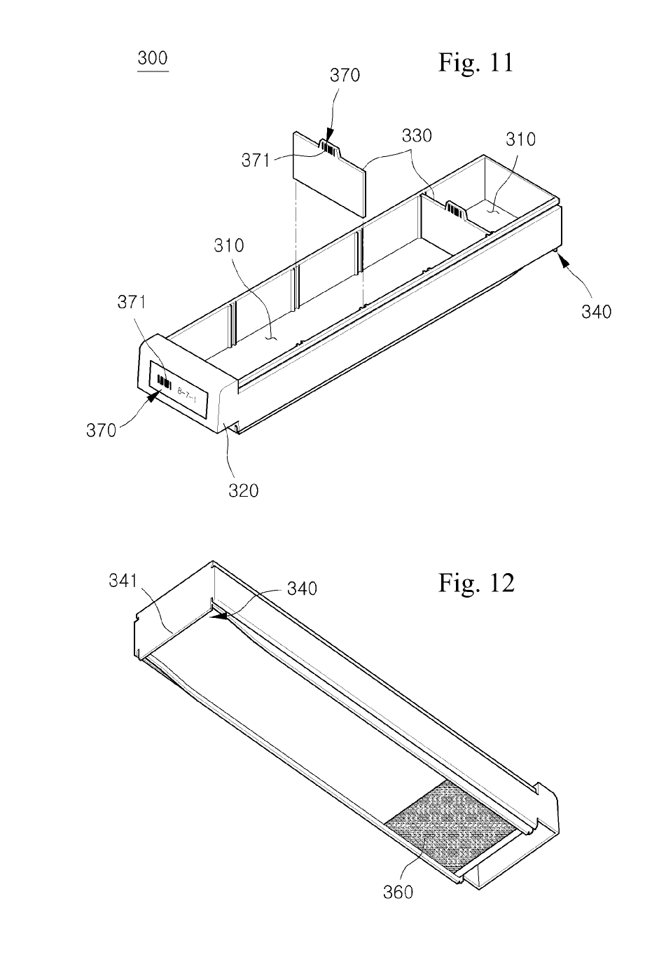

FIG. 11 is a perspective view of a bin according to an embodiment of the present disclosure and FIG. 12 is a bottom view of the bin of FIG. 11.

The bin 300 has a box shape open at an upper side thereof and stores a number of the same kind medicine in an accommodation space 310 defined in the bin 300. The bin 300 may have a size selected from several standardized sizes corresponding to the sizes of medicine packages.

Since the medicine management apparatus is provided with a plurality of bins, a user cannot search for desired medicine based on memory of a position of a certain bin storing the medicine. Each of the bins placed on the shelf is provided with an identification unit 370 which includes identification information for distinguishing one bin from another, such that the controller identifies the respective bins and information of medicines in the respective bins with reference to a database. Accordingly, when a user requests a certain medicine through the input/output units, the controller provides the user with information of a current stock of the medicine and a position of the medicine, that is, an accurate position of a bin on a shelf which stores the medicine, through the input/output units. Further, the controller upgrades and stores history of stocking and dispense of medicines, and allows the bin receiving the corresponding medicine to be indicated through operation of the rotatable circular carousel and the display device.

Accordingly, the identification unit 370 of each of the bins contains identification information composed of the serial number of each of the bins and the name of the medicine stored in each of the bins, and preferably, preset positions of the bins.

For example, the identification unit 370 may be a barcode 371 as shown in FIG. 11. The barcodes 371 are serially generated by a barcode generator (not show) and printed on silver stickers, which in turn are attached to front sides of the bins 300. Then, a user may specify a medicine to be stored in the certain bin by registering information of the barcode 371 attached to a certain bin 300, a serial number of a shelf, on which the bin will be placed, and a position of the bin (for example, a point separated by 30 cm from the right in a shelf on the second floor) with the controller through an input unit (for example, a portable barcode reader or the like) to generate position information of the bin.

Accordingly, when a user inputs the name of a certain medicine, the controller controls the rotatable circular carousel to place the corresponding shelf at the inlet/outlet port, and the display device then indicates the corresponding position of the medicine with an arrow or the like. Further, in the case where a certain bin is removed from the medicine management apparatus by another person, a user can determined a proper position of the bin in the corresponding shelf by scanning the barcode of the bin when returning the bin to the shelf. Further, when restocking medicine, a user can determine a proper bin by scanning a barcode of the bin to be re-stocked with medicine. The barcode is cheaper than any of the other identification means described below.

Referring to FIG. 11, the barcode 371 is formed at an upper portion on the front side of the bin 300, for example, on an upper surface of a grip 320 of the bin 300. With this configuration, the apparatus allows a user to easily search for a desired bin by reading the barcode of the bin using a barcode reader at the inlet/outlet port without withdrawing the bin from the shelf, thereby enabling convenient inquiry of the bin.

In an alternative embodiment, the identification unit may include a radio frequency identification (RFID) tag (not shown) and an RFID reader (not shown) disposed in the housing to recognize the RFID tags provided to the respective bins longitudinally disposed on the shelf.

As in the barcode, the RFID tag of a certain bin receives and stores position information and medicine information related to the bin in registration of the certain bin with the controller by a user. Accordingly, when a user inputs the name of a certain medicine, the controller controls the rotatable circular carousel and the display device based on the position information and the medicine information stored in the RFID tag to provide the corresponding bin to a user. Further, a certain bin removed from the shelf by another user can be returned to a proper position in the corresponding shelf by reading the RFID tag on the bin using a separate RFID reader.

Furthermore, the RFID tag allows a user to easily determine whether a desired bin is present in the medicine management apparatus. In other words, when a certain bin is removed from the apparatus by another person and a user requests a medicine stored in the bin, the controller recognizes that the RFID tag of the bin is not detected by the reader in the housing, and informs the user of the absence of the bin in the corresponding shelf through the input/output units.

In an alternative embodiment, the identification unit may include a memory chip which contains identification information therein, a transmitter which transmits the identification information of the memory chip, and a receiver which is disposed on the bottom of the shelf and receives the identification information from the transmitter.

When registering a certain memory chip having identification information composed of a serial number of the corresponding bin with the controller, a user inputs the name of a medicine to be stored in the bin to generate and store medicine information in the controller.

The receivers are disposed at regular intervals on the bottom of the shelf. Here, the interval is determined according to the sizes of the bins having standardized sizes. For example, when three types of bins having widths of 10 cm, 20 cm and 40 cm are provided to a certain shelf, the size of the smallest bin is 10 cm and an increased width between the other bins is 20 cm. Thus, the interval is set to 10 cm, which is the least common denominator among the size of the smallest bin and the increased width between the other bins. In other words, the receivers are disposed at an interval of 10 cm on the bottom of the shelf in the longitudinal direction, thereby receiving identification information of each bin regardless of the size of the bins.

The transmitter and the receivers may communicate with each other via wired communication, with the bins secured to a certain position on the bottom of the shelf, or may communicate with each other via wireless communication, irrespective of whether or not the bin is secured on the bottom of the shelf.

In this case, since the bins received on the shelf are frequently moved in front of the inlet/outlet port, wireless communication between the transmitter and the receivers is preferable to wired communication therebetween. Here, any receiver may receive identification information together with other identification information transmitted from the transmitters of a bin directly disposed above the receiver and bins adjacent the receiver. In this case, by using ultrasound wireless communication capable of providing distance information of the transmitter based on time-of-flight, the receiver select only identification information of the bin directly disposed above the receiver, thereby solving congestion resulting from wireless communication. Here, the wireless power supply described above or a battery provided to each of the shelves and bins may serve as a power source for the identification unit and the transmitter.

Further, position information and identification information of the bin obtained by the receivers, and inherent identification information of the receivers are sent to and collected by the controller via other wireless communication methods, and the controller can specify positions of bins on each shelf based on the inherent identification information of the receivers, the identification information, the medicine information, and the position information of the bins.

In this case, when a certain bin is placed at any location on any shelf, position information of the bin can be determined by the corresponding receiver, thereby further improving user convenience.

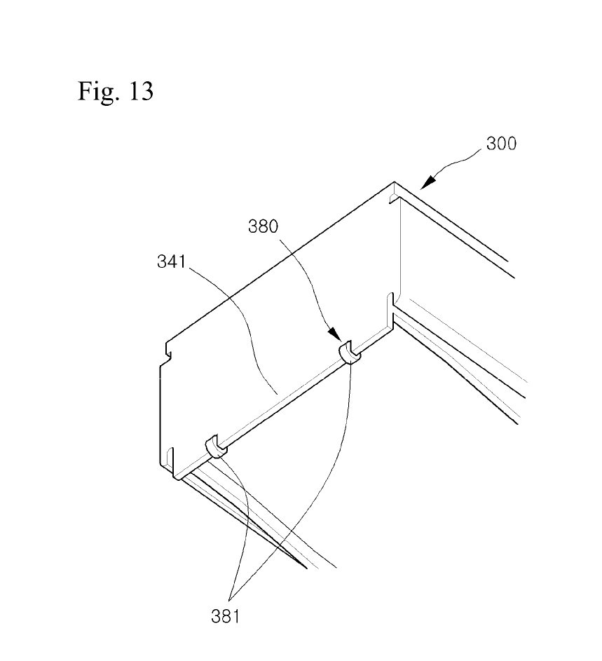

FIG. 13 is a perspective view of a bin according to another embodiment.

When a certain bin is used to store many kinds of a few medicines, a problem of the use of a remaining space can arise. To solve this problem, partitions 330 may be provided to divide the accommodation space 310 of the bin 300. In this case, to administer medicines received in the spaces divided by the partitions, the identification unit 370 may be provided to each of the partitions 330.

In this case, a few medicines can be stored in a single bin, thereby further enhancing space utilization through reduction of the remaining space in the bin. Furthermore, there is another advantage in that the medicines can be administered by the identification units provided to the partitions.

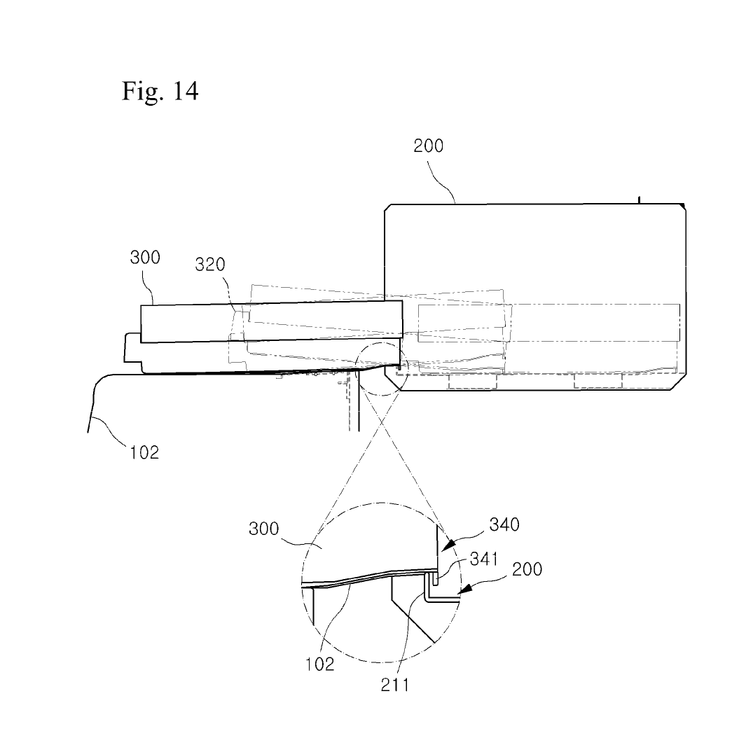

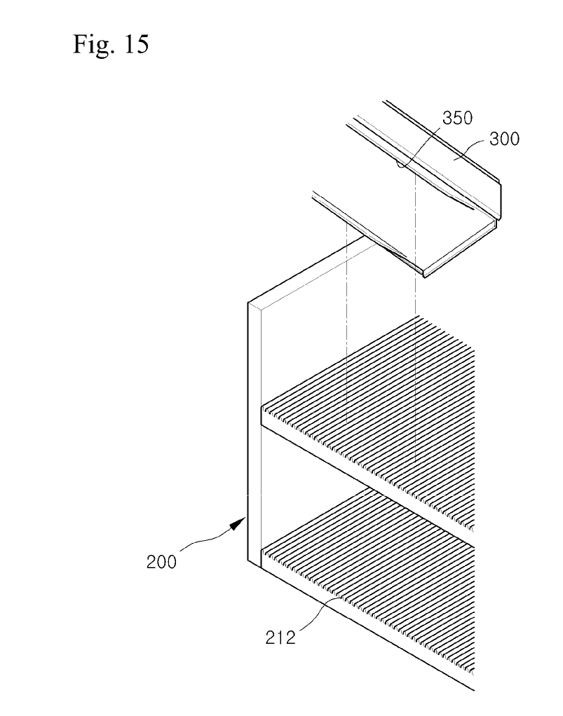

Next, a complete separation preventing structure of the bin will be described with reference to FIGS. 12 and 14.

To stock or dispense medicine to or from the bin 300 on the shelf 200, the bin 300 must be inserted into or pulled from the shelf 200 through the inlet/outlet port 101. In this case, the entirety of the bin 300 can be inadvertently removed from the shelf 200. Thus, to prevent complete separation of the bin 300 from the shelf 200 when the bin 200 is pulled from the shelf 200, the bin 300 may be provided with a latch portion 340 configured to be caught by a threshold 211 formed at a front bottom edge of the shelf 200.

Specifically, the threshold 211 protrudes upwards from the front bottom edge of the shelf 200, and the bin 300 is depressed at a rear portion thereof such that a latch plate 341 can be formed on a rear bottom edge of the bin 300 to be caught by the threshold 211. Furthermore, the bottom of the inlet/outlet port 101 is convexly formed corresponding to the depressed shape of the rear portion of the bin 300. Thus, when a user raises a grip 320 to tilt the bin and pulls the bin forward from the inlet/outlet port 101, the latch plate 341 of the bin 300 is caught by the threshold 211 so that the bin is not additionally moved forwards. Then, when the user places the bin 300 on the rack 102, the bottom of the inlet/outlet port contacts the depressed portion of the bin to allow the bin to be horizontally seated thereon.

It should be understood that a user can pull the bin 300 from the shelf 200 by lifting the bin 300 so as to prevent the latch plate 341 from being caught by the threshold 211.

As such, the apparatus is configured to prevent the entirety of the bin from being inadvertently separated from the shelf, thereby reducing the possibility of erroneous placement of the separated bin to an undesired position.

FIG. 15 is a perspective view of the bin according to the other embodiment in use.

During operation of the rotatable circular carousel, vibration is generated from the shelf, causing the bin seated on the bottom of the shelf to move from side to side. In this case, since the position of the bin indicated by the display unit can differ from the actual position of the bin, it is desirable to prevent such movement of the bin on the shelf.

Accordingly, the shelf 200 is formed with a plurality of elongated grooves 212 that are formed on the bottom of the shelf 200 in the transverse direction of the shelf 200 to prevent the bin 300 from moving from side to side. Further, the bin 300 has protrusions 350 formed on the bottom of the bin 300 to be inserted between the elongated grooves 212.

The protrusion 350 is longitudinally formed on the bottom of the bin 300 in the transverse direction and has a substantially circular cross-section to be inserted between the elongated grooves 212. With this configuration, the protrusions 350 of the bin 300 prevent the bin from moving from side to side in the longitudinal direction while allowing the bin to be smoothly slid in the transverse direction between the elongated grooves 212.

As another element for preventing the longitudinal movement of the bin from side to side, the bin 300 may be provided with a magnet plate 360 as shown in FIG. 12. The magnet plate 360 is formed on a lower surface of the bin, which is made of an iron plate, to secure the bin with magnetic force. The magnet plate 360 may be formed on the overall lower surface of the bin 300. Alternatively, the magnet plate 360 may be formed only on a front part of the lower surface of the bin 300 to reduce force exerted by a user to lift the front part of the bin.

In this case, the magnet plate 360 suppresses the longitudinal movement of the bin to hold the bin at a position where a user places the bin, so that the position of the bin can be accurately specified later by the display unit, thereby improving user convenience.

In addition, a sliding assistor 380 may be provided to the bottom surface of the bin 300 to facilitate forward or backward sliding of the bin when separating or inserting the bin from or into the shelf. The sliding assistor 380 allows the bin to be moved with low force by reducing friction between the bottom of the shelf and the bin 300 when a user lifts or pulls the bin 300 in the front direction or pushes the bin 300 into the shelf.

Specifically, as shown in FIG. 13, the sliding assistor 380 may comprise rollers 381 coupled to a rear end of the bin 300. The roller 381 may be provided to the latch plate 341, which is brought into contact with the bottom of the shelf when the bin 300 is lifted. The roller 381 may have thin thickness to be received in the elongated groove described above or may have a convex circumferential surface.

In this case, the sliding assistor allows the bin to be pulled from or inserted into the shelf by a user with a lower force, thereby reducing user fatigue.

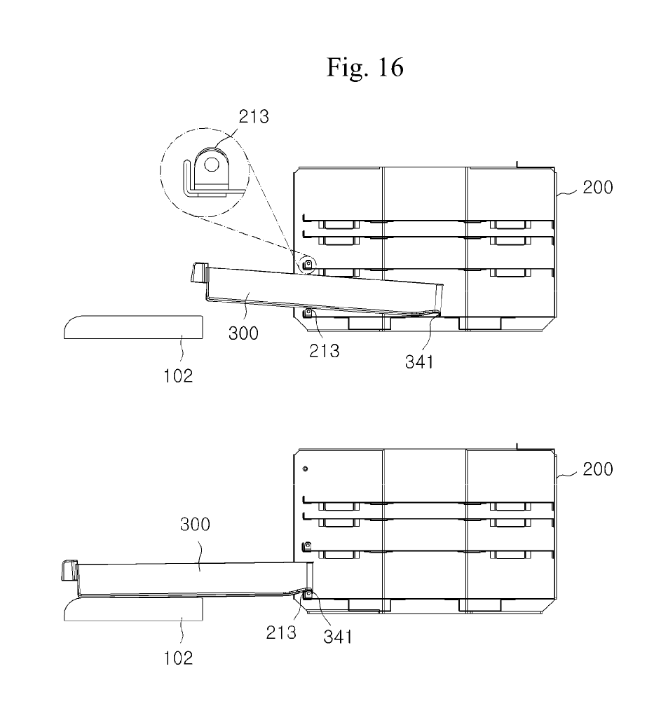

As shown in FIG. 16, the shelf 200 may further include an assistant roller 213, which is disposed on the bottom of the shelf 200 inside the threshold 211 of the shelf 200 and rotates on the bottom of the bin 300 upon separation or insertion of the bin 300 from the shelf or into the shelf. When separating the bin from the shelf, a user lifts the grip of the bin to place the bin on the cylindrical assistant roller 213, which is disposed on the bottom of the shelf 200 inside the threshold 211 or at an upper end of the threshold, and pulls the bin 300 from the shelf 200 in the front direction, so that the bin can be pulled from the shelf with a lower force by the assistant roller 213 which rotates on the bottom of the bin. With this configuration, even when liquid medicine is stored in the bin, making the bin heavy, the assistant roller allows the bin to be easily pulled from or inserted into the shelf.

Further, when the bin 300 is moved in front of the shelf 200 by rotation of the assistant roller 213, the assistant roller 213 is disposed in the depressed portion at the rear side of the bin 300 and the latch plate 341 of the bin is caught by the assistant roller 213, thereby preventing the bin from being completely separated from the shelf in the front direction.

The bin 300 may be made of a transparent material so as to allow medicine stored in the accommodation space of the bin to be identified from the outside. In this case, when a certain shelf is exposed at the inlet/outlet port, the shelf can be easily visually identified based on a trademark or color of the shelf, so that a user can directly identify the corresponding bin without referring to information of the bin specified by the display device or the input/output units.

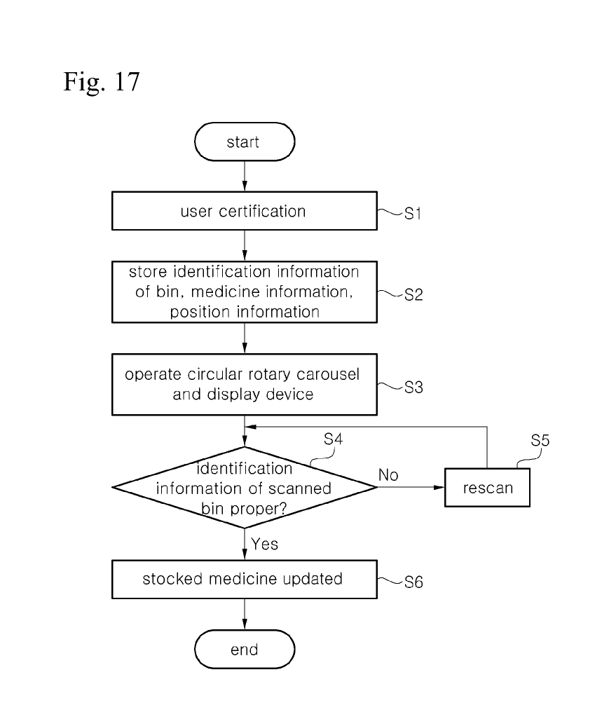

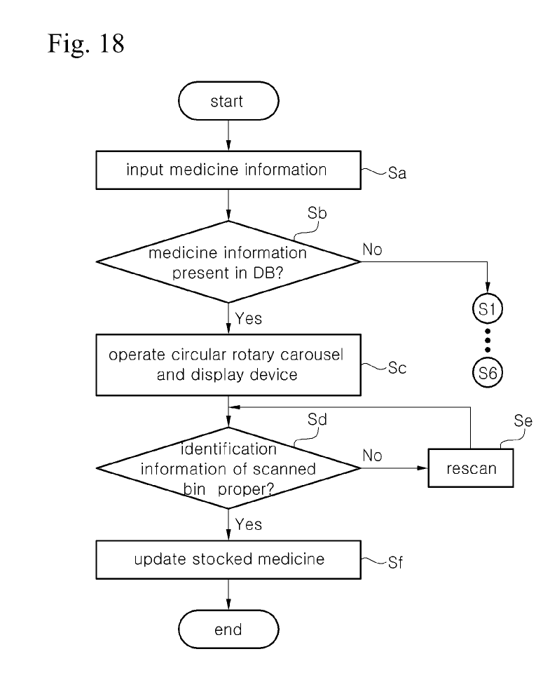

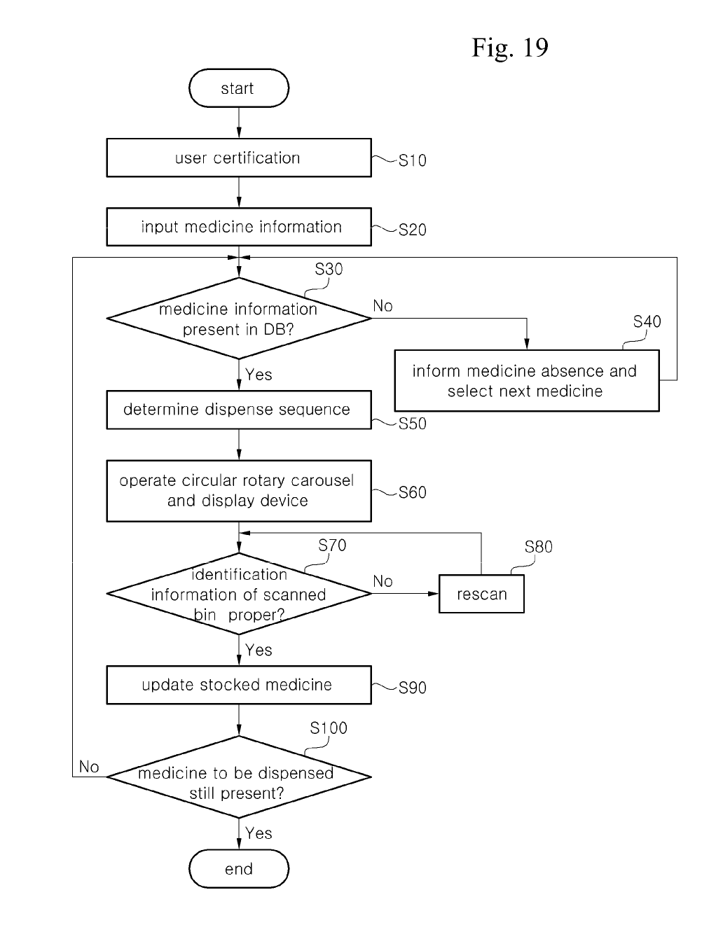

Next, operation of the medicine management apparatus according to the embodiment will be described with reference to FIGS. 17 to 19. The following description will focus on the case of employing the barcode, and can also be applied to the case of employing other identification units including the RFID or the memory chip.

First, a process of stocking medicine will be described.

A user releases the lock to open the main door by inputting an ID and password or using a key in S1.

When stocking medicine initially in a certain bin, a user stores identification information of the bin, position information of the bin, and information of the medicine to be stored in the bin in a database through a barcode reader. Further, the number of medicines to be stocked in the bin, historical data of the medicine such as a date on which the medicine was stocked, expiration date of the medicine, or the like, can also be input to the database, as needed. The aforementioned information is stored in the database through the controller in S2.

The controller operates the rotatable circular carousel based on the input position information to allow a corresponding shelf to move to the inlet/outlet port, and controls the display unit to display a position of the bin on the shelf in S3. A user places the bin receiving the medicines at a position indicated by the display unit and inputs the number of medicines to the controller. The controller stores the number of medicines in a database in S6.

Then, when stocking additional medicine, a user selects a stock status menu of the medicine on the input/output unit to activate a stock status table and input information of the medicine to be stored in Sa. The controller determines in Sb whether the database has the same information as the input information of the medicine, and if the database has the same information, the controller operates the rotatable circular carousel and the display device to allow a proper shelf and a proper bin to be provided to a user such that the user additionally stores the medicine in Sc. If the input information of the medicine is new information, the user is guided to store the medicine according to the procedure described above (S1 to S3, S6).

On the other hand, if the bin suggested by the controller is at full capacity, a user inputs this information to the controller, which in turn suggests empty bins to the user. Then, the user selects one of the bins and the controller controls the rotatable circular carousel and the display unit to provide the selected bin such that the user continues to perform the stocking operation.

In the stocking operation, a user scans a barcode of the bin in S4 to confirm whether the bin indicated by the display unit is correct, and the controller informs the user through the input/output unit as to whether the scanned bin is the proper bin in Sd. If the bin is not the proper bin, the bin may be subjected to additional certification for rescanning the bin in S5, Se.

In the stocking operation, the controller receives data of the number of medicines input by a user and stores the data in the database in S6 and Sf. Further, when historical data of medicines is added to the database, the controller stores the historical data of the medicines in the sequence of expiration dates of the medicines or in the sequence of stocked dates of the medicines such that the medicines can be provided to a user when requested.

In a process of dispensing medicines, user certification is first performed by unlocking the key, as described above in S10, and the controller retrieves the medicines from a database using the names of the medicines input by a user or a list of medicines delivered from a separate apparatus in S20.

The controller determines based on the names of the medicines whether a certain medicine is present on any shelf of the apparatus in S30. If the medicine is not present on any shelf, the controller informs the user of the absence of the medicine through the input/output unit and retrieves the next medicine according to user selection in S40. If the next medicine is present in a certain bin, the process proceeds directly to the operation of dispensing the medicine in S60. Alternatively, the controller may determine a sequence of dispensing the medicine with reference to historical data of the medicine in S50.

After a certain medicine to be dispensed is determined, the controller controls the rotatable circular carousel to allow a shelf receiving an associated bin to move to the inlet/outlet port and controls the display unit to display or indicate the associated bin in S60.

When a user scans the bin, the controller receives information of the bin and determines whether the bin is a proper bin storing the medicine in S70. If it is determined that the indicated bin is not the proper bin, the controller informs the user of this determination through the input/output units and requests the user to rescan another bin in S80. If the indicated bin is the bin storing the medicine, the user pulls the bin from the shelf to remove a desired amount of medicine and inputs the removed number of medicines through the input/output unit.

After the medicine is removed from the bin, the controller updates the number of medicines in the database in S90. If the same kind of medicine is present in other bins or shelves and medicine to be dispensed remains, the other shelves or bins storing the medicine to be dispensed in the next sequence can be provided to the user in S100.

When all amounts of desired medicine are completely dispensed and the user inputs completion of the medicine dispensing operation, the controller notifies the user of changes made to the database through the input/output units.

Since the database is updated in this manner, the apparatus according to this embodiment may directly inform a user of stock circumstance and allows the user to recognize and remove a medicine ending an expiration date thereof. In addition, if some medicines to be dispensed must be provided only to an authorized person, the apparatus requests an additional ID and password for the medicines to ensure security.

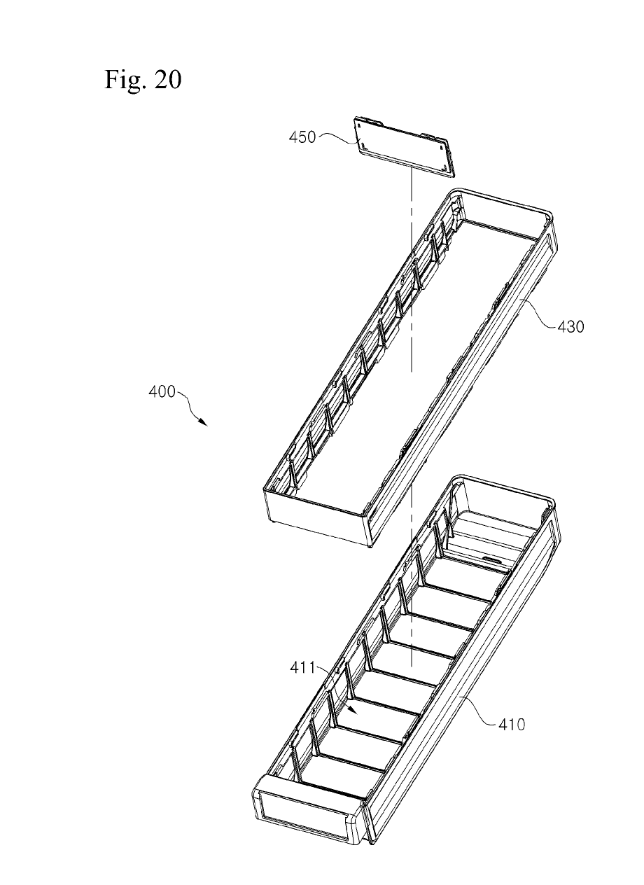

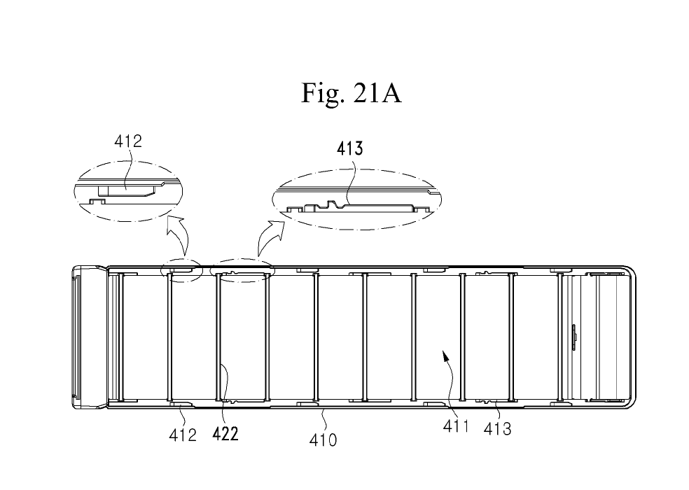

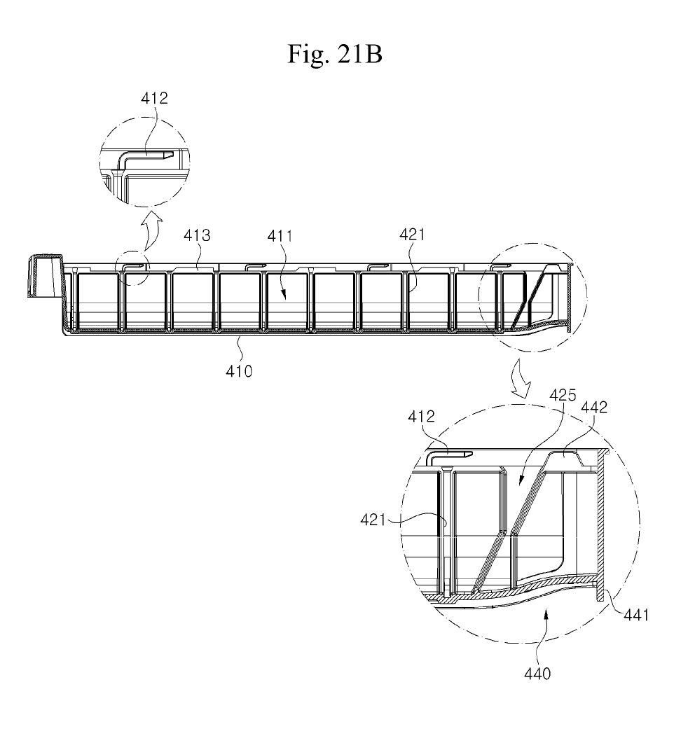

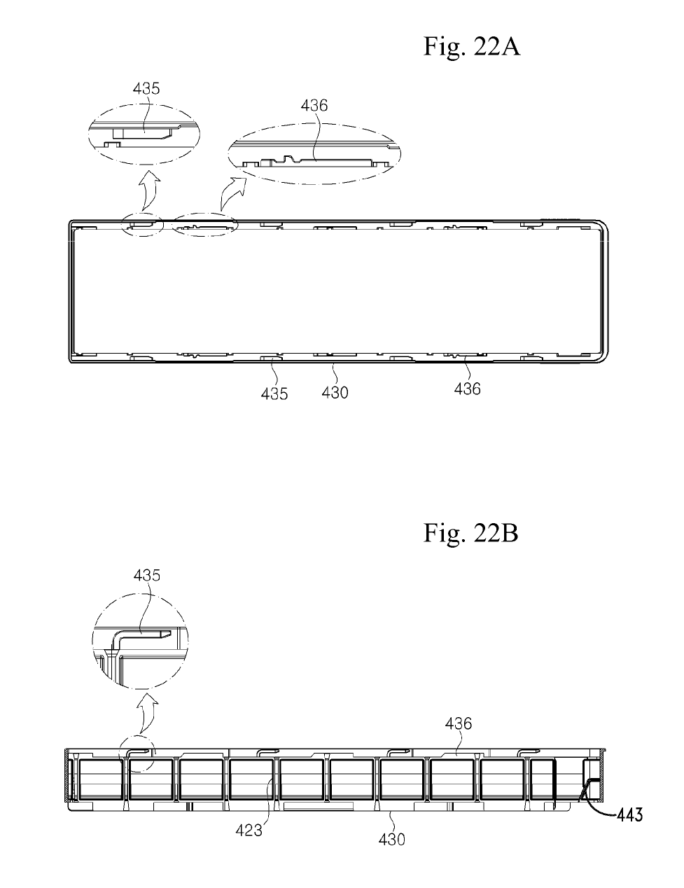

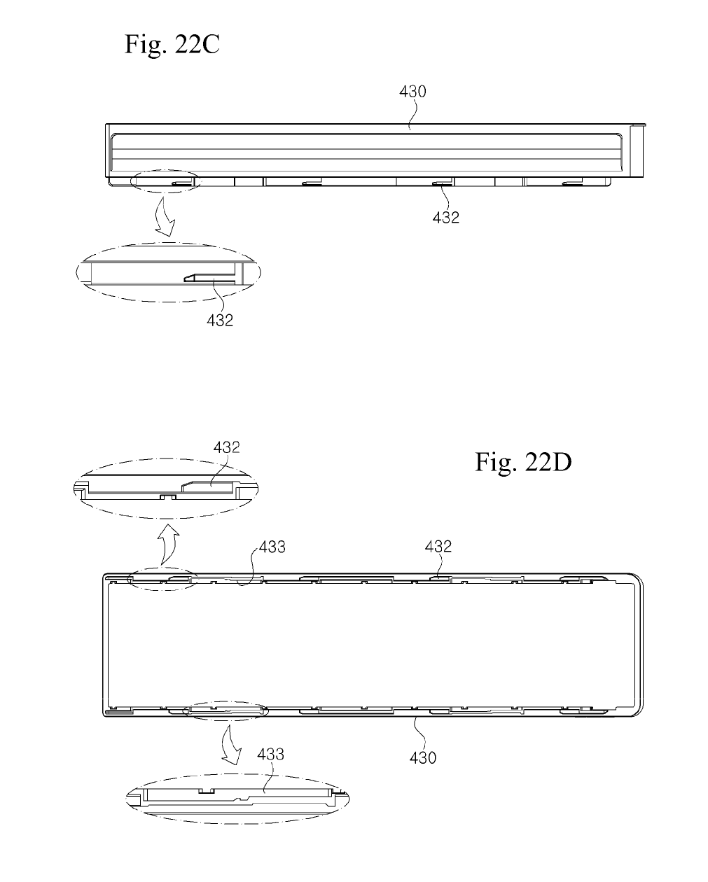

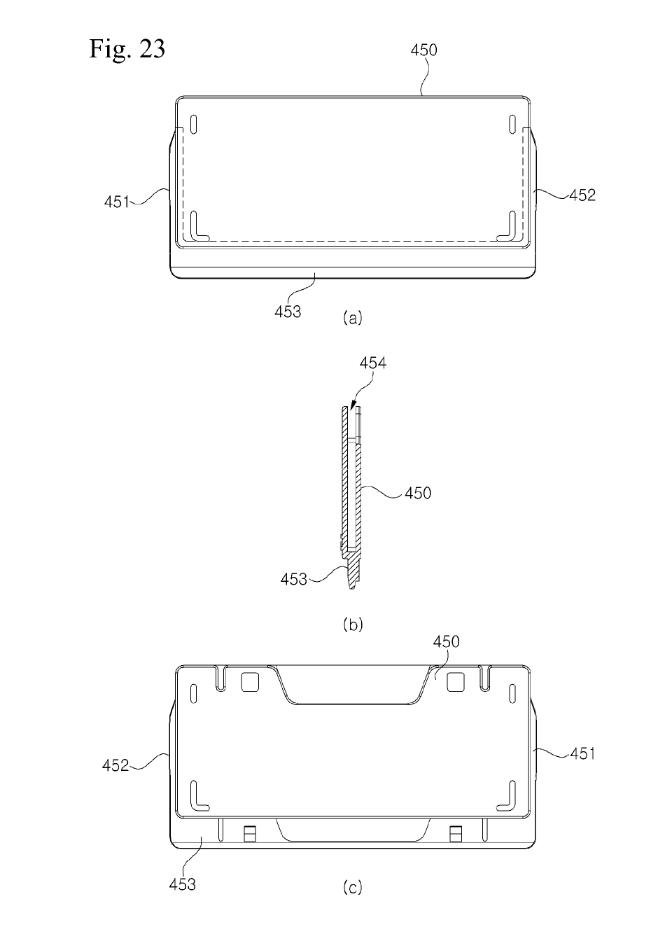

FIGS. 20 to 23 illustrate a bin according to a second embodiment of the present disclosure. Specifically, FIG. 20 is a perspective view of a bin for a medicine management apparatus according to a second embodiment of the present disclosure, FIG. 21A is a plan view of a body of the bin of FIG. 20, FIG. 21B is a side sectional view of the body of the bin of FIG. 20, FIG. 22A is a plan view of an elongated case of the bin of FIG. 20, FIG. 22B is a side sectional view of the elongated case of the bin of FIG. 20, FIG. 22C is a side view of the elongated case of the bin of FIG. 20, FIG. 22D is a bottom view of the elongated case of the bin of FIG. 20, and FIG. 23 is a view of a partition of the bin of FIG. 20.

The bin 400 according to the second embodiment includes a box-shaped body 410 open at an upper side thereof and an elongated case 430 coupled to an upper end of the body 410 to increase the height of the bin 400. The bin 400 according to the second embodiment is substantially the same as the bin 300 according to the first embodiment except for the elongated case 430 for increasing the height of the bin 400. Accordingly, the following description of the bin according to the second embodiment will focus on different components from the first embodiment and the same or similar components will be denoted by the same reference numerals as those of the first embodiment.

In the bin of this embodiment, the body 410 and the elongated case 430 may be detachably coupled to each other by sliding a lower end of the elongated case 430 into an upper end of the body 410.

For coupling between the body 410 and the elongated case 430, the body 410 has a plurality of first coupling protrusions 412 and a plurality of first resilient protrusions 413 formed on an outer upper perimeter of the body 410, more specifically, along outer right and left upper sides of the body 410 in the longitudinal direction, and the elongated case 430 has a plurality of second coupling protrusions 432 and a plurality of second resilient protrusions 433 formed on an outer lower perimeter of the elongated case 430, more specifically, along outer right and left lower sides of the elongated case 430 in the longitudinal direction.

As shown in FIGS. 21A and 21B, the first coupling protrusion 412 has a clamp shape protruding towards the interior of the body 410, that is, an accommodation space 411, and the first resilient protrusion 413 is protruded towards the outside of the body 410, that is, an opposite side of the accommodation space 411.

On the contrary, as shown in FIGS. 22C and 22D, the second coupling protrusions 432 protrude towards the outside of the elongated case 430, that is, an opposite side of the accommodation space 411, and have a shape corresponding to the first coupling protrusion 412, and the second resilient protrusions 433 protrude towards the interior of the elongated case 430, that is, the accommodation space 411.

In this embodiment, the number of each of the first and second coupling protrusions 412, 432 on the right and left sides is four and the number of each of the first and second resilient protrusions 413, 433 on the right and left sides is three. However, it should be understood that the numbers of these components can be changed as needed.

As shown in FIGS. 22A and 22B, the elongated case 430 may further include third coupling protrusions 435 and third resilient protrusions 436 formed on the outer upper perimeter thereof and having the same shapes as those of the protrusions formed on the outer upper perimeter of the body 410, thereby allowing other elongated cases 430 to be continuously stacked one above another.

The body 410 is formed therein with insertion grooves 421 separated at regular intervals from each other such that partitions 450 can be inserted into the grooves 421, and the elongated case 430 is also formed therein with insertion grooves 423 separated at the same intervals as those of the insertion grooves 421. Accordingly, it is possible to insert or remove the partitions 450 when the body 410 is coupled to the elongated case 430.

As shown in FIG. 21B, to prevent the entirety of the bin from being unintentionally separated from the shelf, the bin 400 is provided with a latch part 440 including a latch plate 441, which is configured to be caught by the threshold 211 of the shelf 200. Further, the body 411 may be formed with a partition receiving groove 425 for temporarily storing a remaining partition 450.

As shown in FIGS. 21B and 22B, the body 410 is formed at a rear upper end thereof with a slanted protrusion 442 and the elongated case 430 is formed at a rear lower end thereof with a step 443. Accordingly, the step 443 is moved over the slanted protrusion 442 simply by pushing the elongated case 430 towards the rear of the body 410 to separate the elongated case 430 from the body 410, thereby allowing easy separation of the elongated case 430 from the body 410.

Referring to FIG. 23, (a) illustrates a front view of the partition 450, (b) illustrates a side-sectional view of the partition 450, and (c) illustrates a rear view of the partition 450. When the body 410 is not coupled to the elongated case, the partition 450 may be inserted into the insertion groove 421 of the body 410. When the body 410 is coupled to the elongated case 430, the partition 450 may be inserted into the insertion grooves 421, 423 of the body and the elongated case.

For this purpose, the partition 450 is formed at opposite sides thereof with opposite insertion portions 451, 452 having a proper thickness to be inserted into the insertion grooves 421, 423, and at a lower end thereof with a bottom insertion portion 453 having a proper thickness to be inserted into a bottom groove 422 of the partition 450, which is aligned with the insertion groove 421 and concavely formed on the bottom of the body 410. Further, the partition 450 is formed at an upper end thereof with a partition groove 454, which allows two or more partitions 450 to be coupled to each other in the vertical direction. The bottom insertion portion 452 may be at least partially inserted into the partition groove 454, or preferably completely inserted into the partition groove 454.

A barcode, a memory chip or the like may be attached to such a partition 450 or received therein to show information regarding a medicine received in the bin. Further, the partition may be made of a transparent material for easy identification with the naked eye.

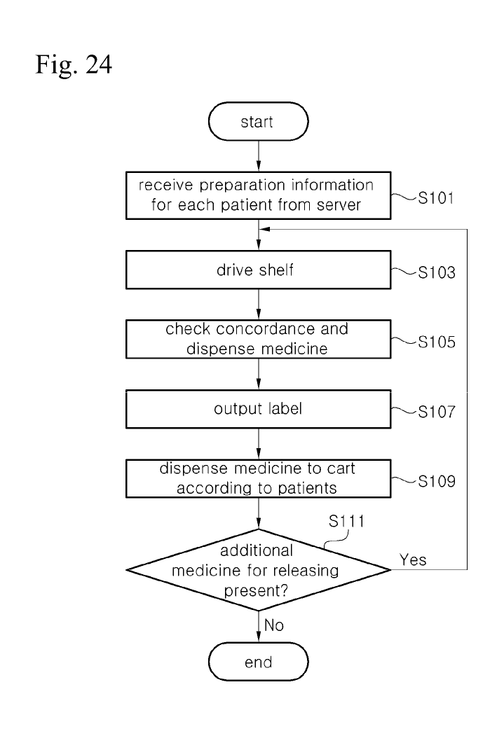

Next, a medicine management method using a medicine management apparatus according to an embodiment will be described with reference to FIGS. 24 to 27.

First, a process of dispensing a medicine according to the medicine management method will be described with reference to FIG. 24. When receiving prescription data from corresponding database servers of drugstores or hospitals, the medicine management apparatus 100 resorts the prescription data according to shelves 200 in the apparatus 100, which stores medicines to be dispensed according to the prescription data for patients in S101.

Then, the circular carousel 1 is operated to move an associated shelf 200 having bins 300, which store the medicines to be dispensed according to the resorted prescription data, to the inlet/outlet port 101 of the apparatus in S103. At the same time, the management apparatus may display information of medicines, such as such as positions and amounts of the medicines, to be dispensed to the patients, through the display device 5.

Then, barcodes of the bins 300 are scanned to dispense the medicines from the bins 300 on the shelf 200 positioned at the inlet/outlet port 101 in S105. In this case, before dispensing the medicines, a user may verify that the prescription data and the medicines match, and then store the dispensed amount of medicines through the input/output unit 103.

Next, a user outputs a label printed with information regarding the dispensed medicines in S107 and attaches the label to a container such as a zipper bag or to a cart 500 having a plurality of compartments, which will accommodate the medicines.

The medicines are sorted and accommodated in the container or the corresponding compartment 501 of the cart 500, to which the label is attached, in S109. After completing sorting and accommodation of the medicines, the label attached to the container or the corresponding compartment 501 is scanned using a barcode reader or the like. According to this scanned information, if additional medicine is to be dispensed, the process returns to S103, and if there is no medicine to be dispensed, the process is ended in S111.

According to an alternative embodiment, the container or the cart may be configured such that information of the medicines to be received in the corresponding compartment of the cart can be identified or confirmed using a PDA or a PC in the apparatus, instead of outputting and attaching the label printed with information of the medicines to the corresponding compartment of the cart.

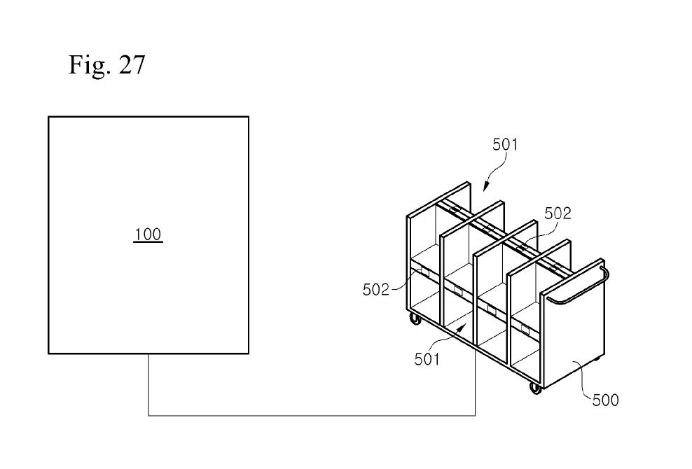

As shown in FIG. 27, the medicine management apparatus according to the embodiment may further include the cart 500, in which the plurality of compartments 501 are divided from each other by partitions. The apparatus 100 (specifically, the controller in the housing 100a) and the cart 500 may be configured to send or receive information through wired or wireless communication. Further, each of the compartments 501 in the cart 500 may be provided with a display device 502 to display information of a medicine received in each of the compartments 501 through exchange of the information with the medicine management apparatus 100 or by direct input of the information by a user.

When the apparatus and the cart can exchange information with each other and the cart is provide with the display device 502, a target compartment in the cart 500 for receiving a medicine dispensed from a bin 300 of a certain shelf 200, and an amount of medicine to be received in the target compartment can be automatically displayed on the display device 502, thereby improving user convenience.

According to the present disclosure, since operation of dispensing medicines from the medicine management apparatus 100 and placing the medicines in the corresponding compartments 501 of the cart 500 is manually carried out, each of the compartments 501 is provided with an inspection tester such as a scanner to allow an operator to confirm whether the medicines displayed on the display device 502 are placed in the correct compartments 501, thereby preventing mistakes when stocking the cart 500. The inspection tester compares information of the medicine actually placed in the compartment with information of a desired medicine to be placed in the corresponding compartment, thereby preventing erroneous placement of the medicine.

Furthermore, the cart 500 may include a termination button to allow a subsequent operation to be continued through reception and transmission of subsequent prescription data (according to patients or medicines) after completing placement of medicines in the respective compartments according to certain prescription data (according to patients or medicines). When the termination button is pushed, the controller of the apparatus 100 recognizes termination of the operation of placing the medicines according to the certain prescription data and drives a shelf for dispensing other medicines according to the subsequent prescription data.

In the method and apparatus described above, since desired medicines are dispensed according to the shelves in the medicine management apparatus, that is, the kind of medicine, and provided to the cart 500 after sorting, it is possible to reduce time and effort for the dispensing operation as compared with the operation of dispensing the medicines according to patients.

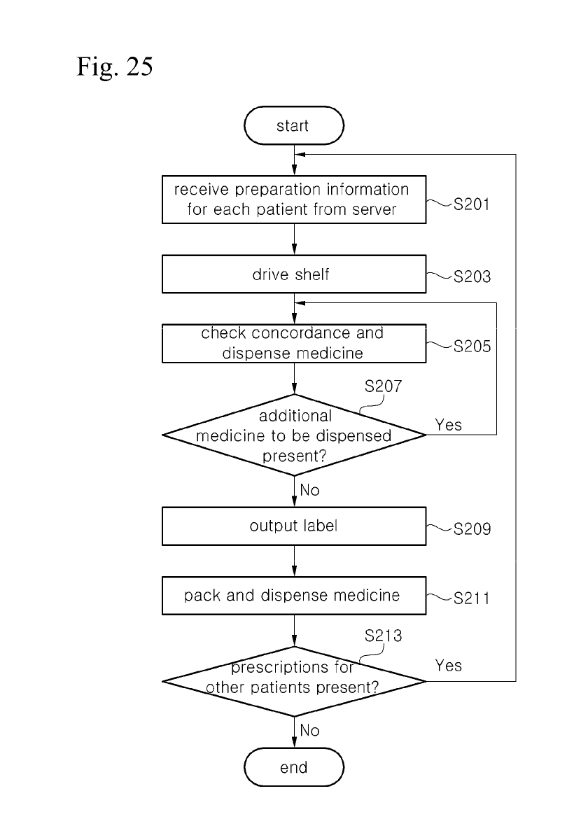

FIG. 25 is a flowchart of a management method for comparison with the medicine management method of FIG. 24. Compared with the medicine management method according to the embodiment by which medicines are dispensed according to the kind of medicine, the comparative method dispenses the medicines according to patients.

First, the medicine management apparatus 100 receives prescription data from corresponding databases of drugstores or hospitals, and resorts medicines for patients according to the patients in S201.

Then, the circular carousel 1 is operated to move the shelves 200 having bins 300, in which the medicines are stored, according to the resorted data to an inlet/outlet port 101 of the apparatus in S203.

Then, barcodes of the bins 300 are scanned to dispense the medicines from the bins 300 on the shelf 200 positioned at the inlet/outlet port 101 in S205. In this case, before dispensing the medicines, a user may check concordance between the prescription data and the medicines, and then store the dispensed amount of medicines through the input/output units 103.

If there are two or more kinds of medicines to be dispensed to a certain patient, it is determined in S207 that additional medicine needs to be dispensed, the process returns to S203, in which the circular carousel 1 is operated to move the shelf 200 having a bin 300, which stores the medicine, to the inlet/outlet port 101 of the apparatus, and the dispensing operation is repeated until no more medicine to be dispensed to the patient is present.

When all of the medicines prescribed to the corresponding patient are dispensed, a user outputs a label printed with information of the dispensed medicines in S209 and attaches the label to a container such as a zipper bag or the like, which will accommodate the medicines.

The dispensed medicine is packed in a labeled container, which in turn is discharged, in S211. When packaging and discharging the medicine are completed, the label attached to the container is scanned using a barcode reader or the like. According to this scanned information, if additional medicine needs to be dispensed to another patient, the process returns to S201, and if no additional medicine needs to be dispensed, the process ends in S213.

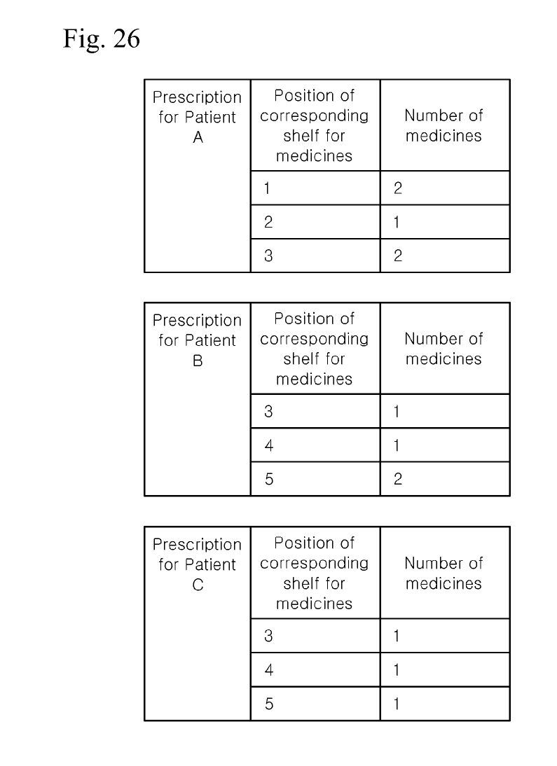

Next, the method of dispensing medicines according to the kind of medicine as shown in FIG. 24 will be compared with the method of dispensing medicines according to patients as shown in FIG. 25. In both methods, the medicines are prepared according to prescriptions as shown in FIG. 26.

When the medicine management apparatus receives the three types of prescription data shown in FIG. 26 from corresponding databases of drugstores or hospitals to dispense medicines according to patients, the carousel is driven three times to move corresponding shelves for each of Patients A, B and C. That is, the carousel is driven 9 times. On the contrary, when the medicines are dispensed according to the kind of medicine, the carousel is driven once to move Shelf 1 for dispensing medicines for Patient A, twice to move Shelf 2 for dispensing a medicine for Patient A, three times to move Shelf 3 for dispensing medicines for Patients A and B, four times to move Shelf 4 for dispensing medicines for Patients B and C, five times to move Shelf 5 for dispensing medicines for Patients B and C, and six times to move Shelf 6 for dispensing medicines for Patient C. Thus, the carousel is driven 6 times for dispensing the medicines.

Consequently, compared with the process of dispensing medicines according to patients, the process of dispensing medicines according to the kind of medicine may reduce the total number of driving times of the carousel to move the shelves, thereby reducing time for dispensing medicines.

Embodiments of the present disclosure may provide a cart 500 having a space partitioned by a plurality of compartments 501 for delivering medicines dispensed from a medicine depository 100, such as a storehouse, a drugstore shelf, an automatic medicine storage and dispensing apparatus, and the like, to a patient, and a medicine management method using such a medicine cart.

As the medicine depository, the automatic medicine storage and dispensing apparatus includes a plurality of shelves coupled to a vertically disposed rotatable circular carousel, and a plurality of containers storing medicines and disposed inside the shelves.

As shown in FIG. 27, the medicine depository 100 and the cart 500 may be configured to exchange information with each other via wired or wireless communication. Further, each of the compartments 501 in the cart 500 may be provided with a display device 502 to display information of a medicine received in each of the compartments 501 through information exchange of the medicine depository 100 or by direct input of the information by a user.

When the medicine depository and the cart can exchange information with each other and the cart is provide with the display device 502, a target compartment in the cart 500 for receiving a medicine dispensed from a certain place of the medicine depository 100, and an amount of medicine to be received in the target compartment can be automatically displayed on the display device 502, thereby improving user convenience.

According to the present disclosure, since operation of dispensing medicines from the medicine management apparatus 100 and placing the medicines to the corresponding compartments 501 of the cart 500 is carried out manually, each of the compartments 501 is provided with an inspection tester such as a scanner to allow an operator to confirm whether the medicines displayed on the display device 502 are placed in the correct compartments 501, thereby preventing mistakes when stocking the medicine cart 500. The inspection tester compares information of the medicine actually placed in the compartment with information of a desired medicine to be placed in the corresponding compartment, thereby preventing erroneous placement of the medicine.

Furthermore, the cart 500 may include a termination button to allow a subsequent operation to be continued through reception and transmission of subsequent prescription data (according to patients or medicines) after completing placement of medicines in the respective compartments according to certain prescription data (according to patients or medicines). When the termination button is pushed, a controller of the medicine depository 100 recognizes termination of the operation of placing the medicines according to the certain prescription data and drives a shelf for dispensing other medicines according to the subsequent prescription data.

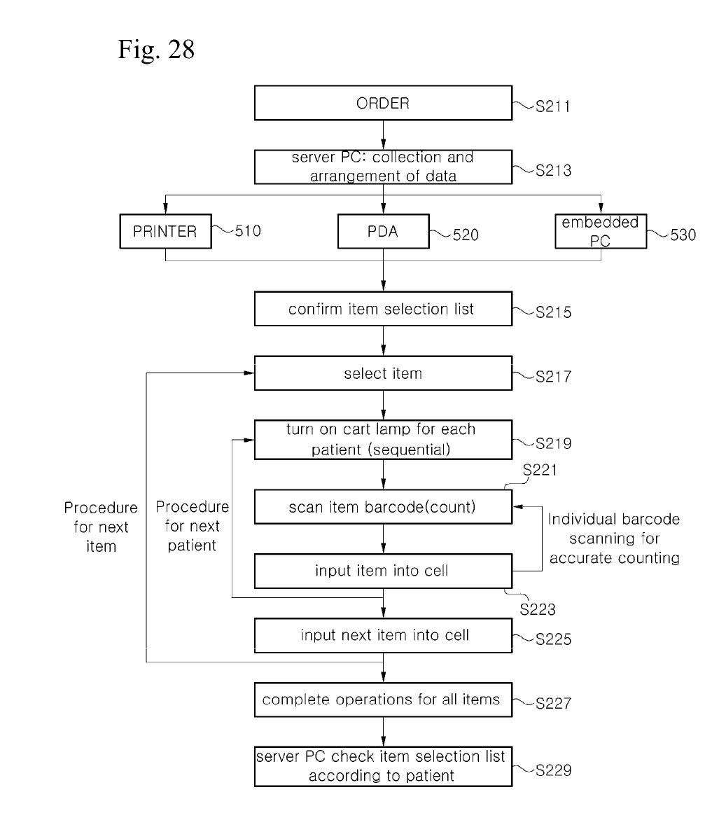

Next, the medicine management method using the cart according to the embodiment will be described with reference to a flowchart of FIG. 28.

When receiving information of medicines to be dispensed to patients, that is, an order of certain medicines, in S211, a server PC for the medicine depository collects the information of the medicines to be dispensed from the depository and aligns the medicine information according to the kind of medicine or patients, in S213. The server PC may be located inside the medicine depository or outside the medicine depository.

The server PC transfers the aligned medicine information to one of a printer 510, a PDA 520 and an embedded PC 530.

When the printer 510 is used, the printer 510 outputs a barcode or the like, which has the medicine data printed thereon, and a user attaches the barcode to a certain compartment 501 of the cart or to a portion near the compartment 501, in order to confirm whether the medicines are properly placed in the compartment 501. In this case, the cart 500 is provide with a barcode scanner as a data input/output unit, and an LCD as a display device for displaying the data recognized by the barcode scanner. The method using the printer 510 reduces costs for system installation and provides improved software compatibility with other products.

When the PDA is used, the cart can eliminate the need for the barcode scanner as a data input/output unit and the LCD as a display device, and data management can be easily performed. That is, since the PDA may function as the data input/output unit and as the display device, it is possible to read the medicine data and to display a target compartment for receiving a certain medicine when using the PDA in association with the cart.

When the embedded PC is used, the cart may be provided with the embedded PC, the barcode scanner as a data input/output unit, the LCD as a display device, and the like. In this case, an operator may conveniently use both hands, as compared with the case of using the PDA, and the embedded PC may be used to implement various application programs.

Next, a user confirms an item selection list according to the kind of medicine in S215 and selects one of the items, that is, one type of medicine, in S217.

When a certain item is selected, the corresponding compartment for receiving the item, that is, the medicine, may be displayed by lighting a lamp of the corresponding compartment in S219. The lamps may be lit in order of patients.

Then, a user confirms information of the selected item through the barcode of the item and places the selected item, that is, the corresponding medicine, into a cell, that is, the compartment in S223. In this case, when there are two or more of the same kind of items to be placed in the compartment, the barcodes of the items are preferably individually scanned for accurately counting the number of items. In other words, when there are two or more of the same kind of items to be placed in the compartment, the process returns from S223 to S217 to repeat the aforementioned procedures corresponding to the number of the same kind of items to be placed in the compartment.

When placement of the selected item in the compartment for a certain patient is completed, a lamp of a compartment for another patient requiring the selected item is lit. Specifically, if the selected item is prescribed to two or more patients, the process returns to S219 so as to allow placement of the selected item in the compartment for the other patient to be continued after the placement of the selected item in the compartment for the previous patient.

When the selected item is prescribed to many patients and placement of the selected item in the compartments for all of the patients is completed, it is confirmed in S225 whether there is another item, that is, another medicine, to be placed in the compartment, and the process returns to S217, if yes.

When operations for all of the items are completed in S227, the server PC checks whether the operations according to the item selection list are properly completed, based on an item selection list according to the patients, in S229.

Upon confirming that all of the items, that is, all of the medicines, are properly placed in the compartments for all of patients, the medicine cart is delivered by an operator to a hospital.

In the above embodiment, the medicine data or the like is illustrated as being recognized using the barcodes. However, it should be understood that an RFID or the like may also be used to recognize the medicine data.

As such, according to the embodiment, the cart including the compartments allows medicines individually prescribed to patients to be sorted and supplied according to hospital wards, thereby simplifying a medicine supply operation carried out by nurses while ensuring the prevention of pharmaceutical accidents.

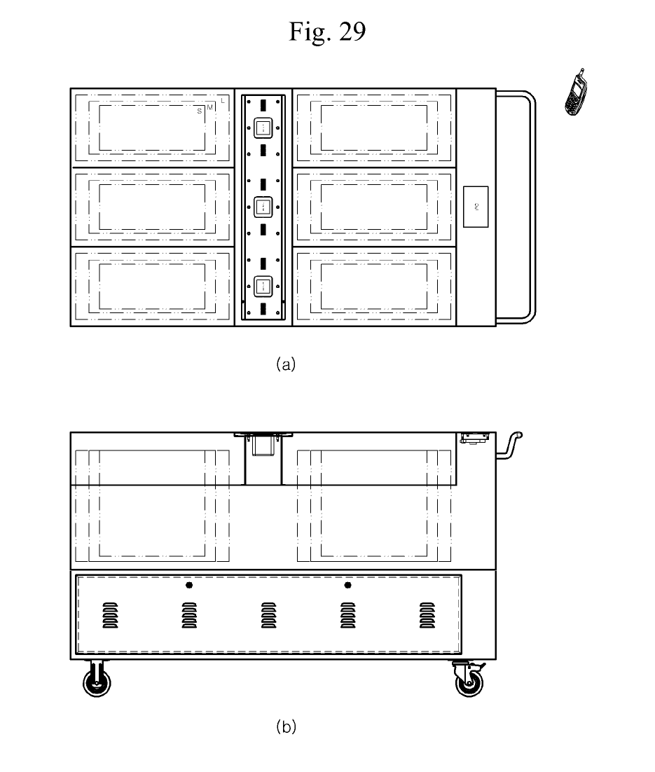

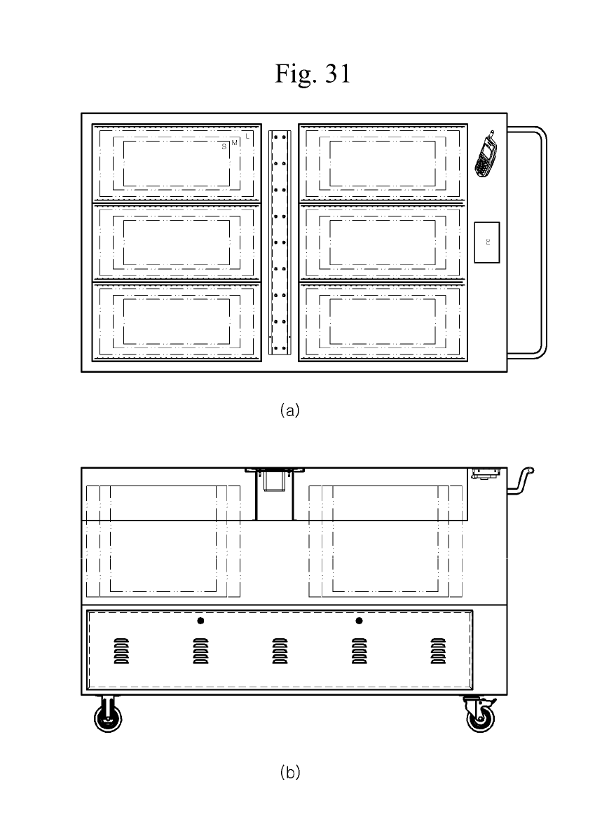

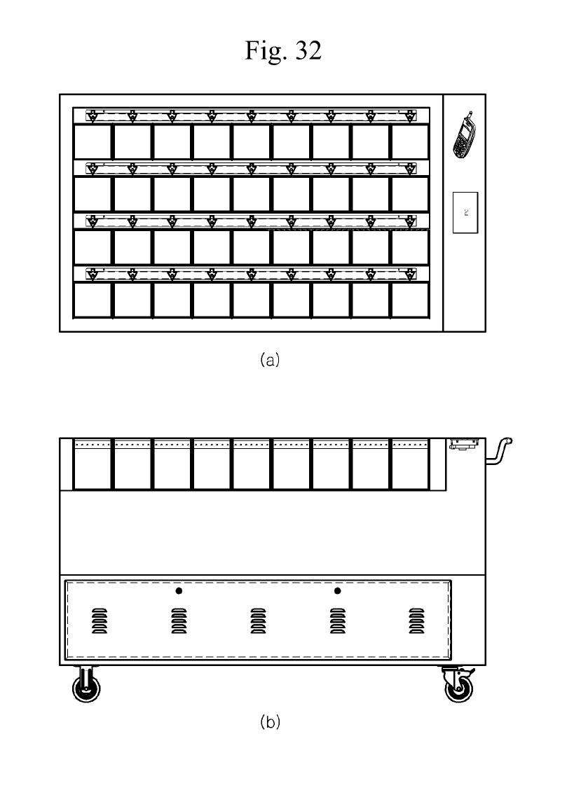

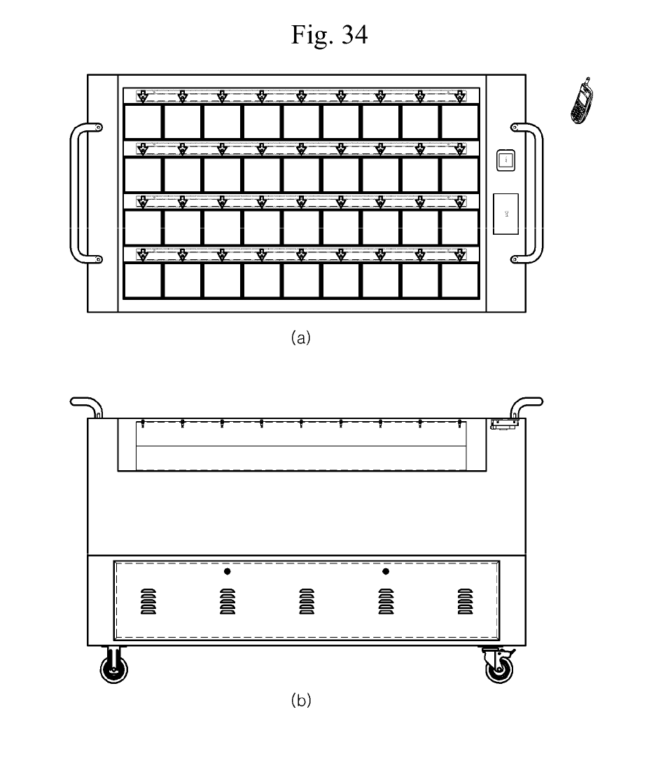

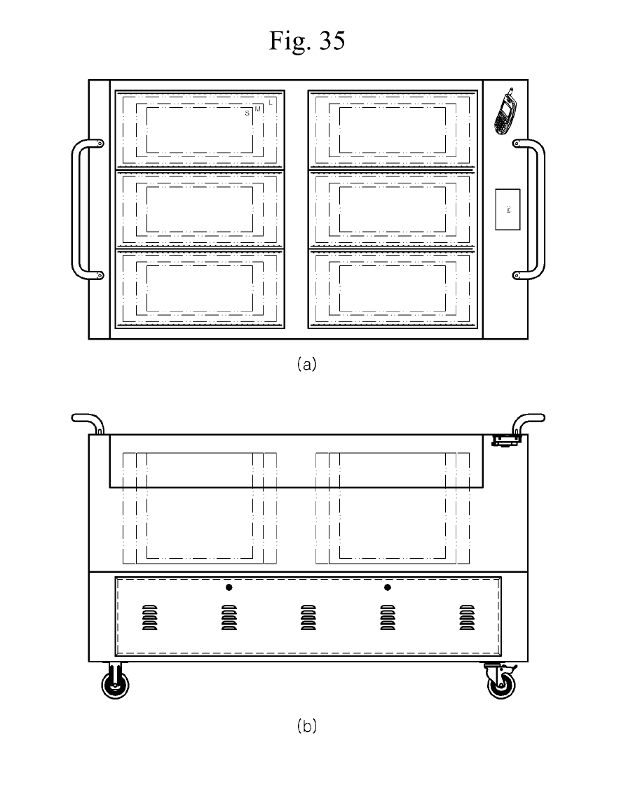

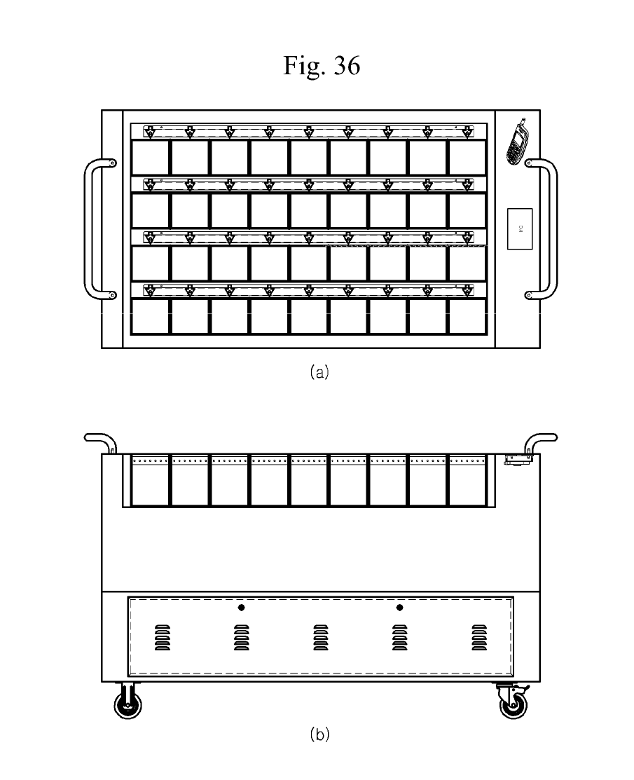

FIGS. 29 to 36 illustrate various modifications of the cart.

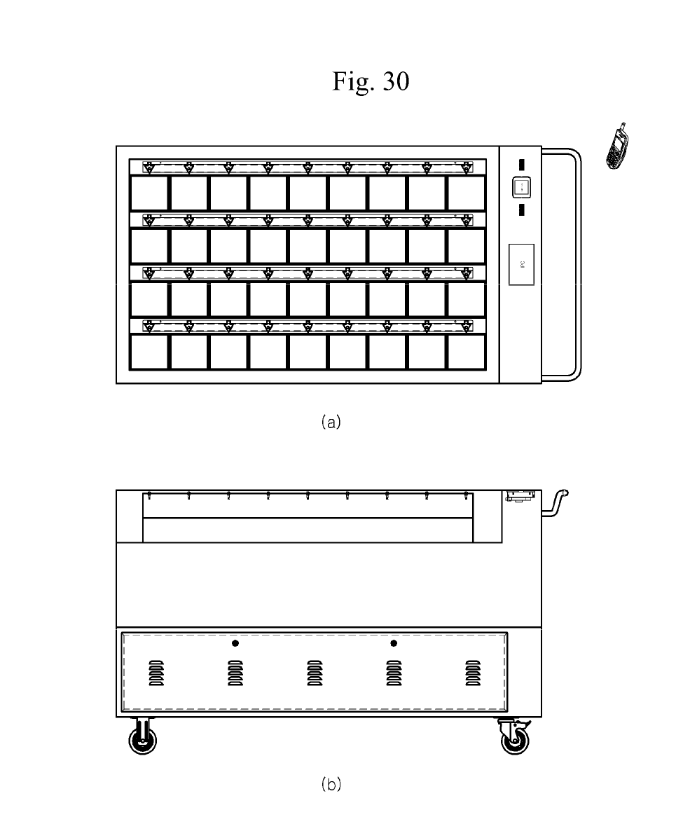

In FIGS. 29, 31, 33 and 35, modified carts are illustrated as including bag-type compartments, and in FIGS. 30, 32, 34 and 36, modified carts are illustrated as including tray-type compartments.

For the bag-type compartments, the bags may have large, middle, and small sizes as indicated by L, M, and S in the figures.

As described above, each of the modified carts may include the compartments and display devices capable of displaying information of medicines received in the corresponding compartments. To display a target compartment for a certain medicine based on information identified by a device such as the barcode scanner or the like, the display device may include a lamp provided to each of the compartments, and an LCD window for displaying information of the certain medicine obtained by scanning with the barcode scanner or the like.

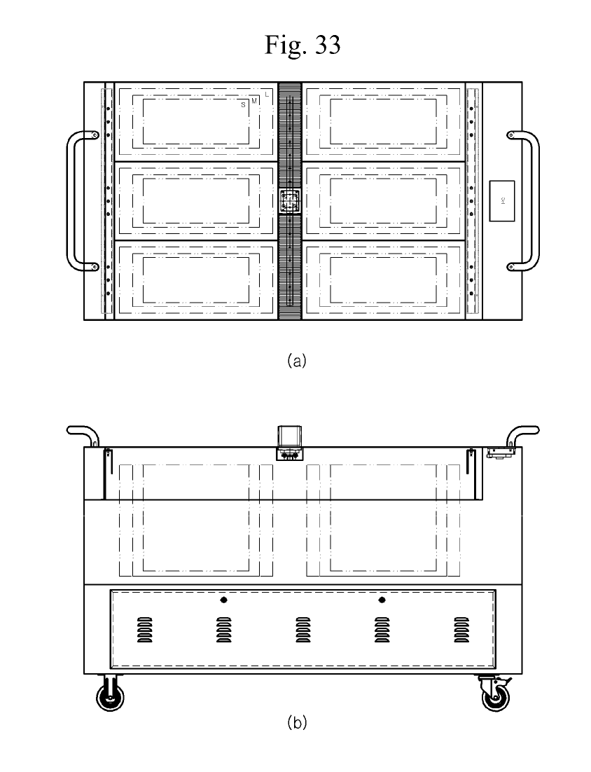

For example, the cart may be provided with a single device such as the barcode scanner for recognition and input of information, which is secured to a predetermined position of the cart, for example, to a position near the LCD window (see FIGS. 30 to 32 and FIGS. 34 to 36), or which is linearly movably disposed at the center of the cart (see FIG. 33). Alternatively, the cart may include a plurality of devices such as the barcode scanner for recognition and input of information on an upper surface thereof (see FIG. 29).

Further, the cart may be provided with a wheel and a grip for movement convenience.

As such, the present disclosure provides a medicine management apparatus that differentiates accessibility to a certain medicine requiring secure handling to prevent unauthorized persons from accessing the medicine, thereby increasing a security level in semi-automated medicine management.

The present disclosure also provides a bin and a medicine management apparatus including the same. The bin receives corresponding medicines in a shelf of the medicine management apparatus and includes an elongated case at an outer upper side thereof or partitions therein. With this configuration, the bin permits easy adjustment of the sizes of spaces for receiving the medicines, thereby enabling efficient use of compartments in the medicine management apparatus.

Further, the present disclosure provides a medicine management apparatus and method, which enable more rapid and easier management of medicines by allowing medicines prepared according to prescriptions to be dispensed according to the kind of medicine rather than according to patients and sorting the dispensed medicines in a cart having a plurality of compartments. Accordingly, the medicines can be dispensed from a medicine depository according to the kind of medicine rather than according to patients, thereby reducing time and effort for dispensing the medicines through a decrease in drive times of a rotary carousel to move shelves.

Further, the present disclosure provides a cart and a medicine management method using the same, by which medicines prepared according to prescriptions are dispensed according to the kind of medicine rather than according to patients and are then sorted in the cart having a plurality of compartments, so that the medicines dispensed from a medicine depository are prevented from being mixed with other medicines and can be accurately delivered to patients. Accordingly, medicines individually prescribed to patients can be sorted and supplied using the cart according to hospital wards or the like, thereby simplifying a medicine supply operation of nurses while ensuring prevention of pharmaceutical accidents.

The various embodiments described above can be combined to provide further embodiments. All of the patents, patent application publications, patent applications, foreign patents, foreign patent applications and non-patent publications referred to in this specification and/or listed in the Application Data Sheet are incorporated herein by reference, in their entirety. Aspects of the embodiments can be modified, if necessary, to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A medicine management apparatus including a plurality of shelves movably coupled to a vertically disposed rotatable circular carousel and a plurality of bins seated on the shelves and accommodating medicines, the apparatus further comprising:
a main door that opens or closes an inlet/outlet port at a front side of a housing of the medicine management apparatus; and
a shelf assistant door that opens or closes a front part of each of the shelves exposed through the inlet/outlet port and is provided with a lock.

2. The apparatus of claim 1, wherein the shelf assistant door comprises a crease screen received in a receiving slit formed at either side of the shelf to open the front part of the shelf and moved along a transfer groove formed on the bottom or ceiling at the front part of the shelf to close the front part of the shelf.

3. The apparatus of claim 2, further comprising: height adjustors provided to the rotatable circular carousel to adjust a distance between adjacent shelves rotatably coupled to the rotatable circular carousel.

4. The apparatus of claim 3, wherein each of the height adjustors comprises a pair of support arms forming a triangular support structure on a chain of the rotatable circular carousel, support members extending from distal ends of the support arms to face each other, and a hinge receptor disposed at either sidewall of the shelf to be adjustable in height and receiving the support members so as to allow rotation of the support members.

5. The apparatus of claim 1, wherein a surveillance sensor is disposed inside the inlet/outlet port to detect an obstacle present in the inlet/outlet port and the controller prevents operation of the rotatable circular carousel or a closing operation of the main door when the surveillance sensor detects the obstacle.

6. The apparatus of claim 1, further comprising: a display device longitudinally disposed along the inlet/outlet port to display an approximate position of a bin indicated by a user with an image relating to the bin.

7. The apparatus of claim 2, wherein each of the shelves is formed at a bottom surface thereof with a plurality of elongated grooves in a transverse direction of the shelf to prevent the bin from moving from side to side, and the bin is formed at a bottom surface thereof with protrusions to be inserted between the elongated grooves.

8. The apparatus of claim 2, wherein the housing is provided with a temperature/humidity regulator for regulating temperature and humidity in the housing.

9. The apparatus of claim 2, wherein one of the shelves is provided with a refrigerating unit that receives power from the housing via a wireless power supply unit to store medicine at low temperatures.

10. The apparatus of claim 2, further comprising: an intermediate plate that divides an interior of each of the shelves.

11. The apparatus of claim 1, further comprising: an identification unit that is provided to each of the bins placed on the shelves and has identification information for distinguishing one bin from another.

12. The apparatus of claim 11, wherein the identification unit comprises a barcode.

13. The apparatus of claim 12, wherein the barcode is attached to an upper surface of a grip formed at a front upper end of the bin.

14. The apparatus of claim 11, wherein the identification unit comprises an RFID tag and the housing is provided with an RFID reader that recognizes the RFID tag provided to each of the bins longitudinally disposed on the shelf.

15. The apparatus of claim 11, wherein the identification unit comprises a memory chip that contains the identification information therein and a transmitter that transmits the identification information of the memory chip, and the shelf is provided at the bottom thereof with a receiver that receives the identification information from the transmitter.

16. The apparatus of claim 11, wherein the bin is provided with partitions that divide an interior of the bin into a plurality of spaces, and the identification unit is provided to each of the partitions.

17. The apparatus of claim 11, wherein the bin comprises a latch portion caught by a threshold formed at a front bottom edge of the shelf to prevent the bin from being completely separated from the shelf when the bin is pulled from the shelf.

18. The apparatus of claim 11, wherein the bin further comprises a sliding assistor that facilitates forward or backward sliding of the bin when the bin is pulled from or inserted into the shelf.

19. The apparatus of claim 17, wherein the shelf comprises an assistant roller disposed inside the threshold of the shelf to rotate on a bottom of the bin when the bin is pulled from or inserted into the shelf.

20. The apparatus of claim 11, wherein the bin comprises a magnet plate formed on a lower surface thereof and attached to a bottom surface of the shelf to prevent the bin from being moved in a longitudinal direction from side to side.

21. The apparatus of claim 11, wherein the bin is made of a transparent material so as to allow the medicine stored in an inner space of the bin to be identified from outside.

22. A bin for a medicine management apparatus for placing and managing medicines on a plurality of shelves, comprising:
a box-shaped body open at an upper side thereof; and
an elongated case detachably coupled to an upper end of the body to increase a height of the bin.

23. The bin of claim 22, wherein the body comprises a plurality of first coupling protrusions and a plurality of first resilient protrusions formed on an upper side of the body, and the elongated case comprises a plurality of second coupling protrusions and a plurality of second resilient protrusions formed on an lower side of the elongated case, for coupling between the body and the elongated case.

24. The bin of claim 23, wherein the first coupling protrusions are protruded towards an interior of the body, the second coupling protrusions coupled to the first coupling protrusion are protruded towards an outside of the elongated case, the first resilient protrusions are protruded towards an outside of the body, and the second resilient protrusions are protruded towards an interior of the elongated case.

25. The bin of claim 24, wherein the elongated case further comprises third coupling protrusions and third resilient protrusions formed on the upper side thereof and having the same shapes as those of the first coupling protrusions and the first resilient protrusions formed on the upper side of the body to allow a plurality of elongated cases to be stacked one above another.

26. The bin of claim 22, wherein the body is formed therein with insertion grooves separated from each other such that partitions can be inserted into the insertion grooves.

27. The bin of claim 26, wherein the elongated case is formed therein with insertion grooves separated from each other such that the partitions can be inserted into the insertion grooves.

28. The bin of claim 22, wherein the body is provided at a rear lower end thereof with a latch plate caught by a threshold of each of the shelves to prevent the entirety of the bin from being unintentionally separated from the shelf.

29. The bin of claim 22, wherein the body is formed therein with a partition receiving groove for temporarily storing a remaining partition.

30. The bin of claim 22, wherein the body is formed at a rear upper end thereof with a slanted protrusion and the elongated case is formed at a rear lower end thereof with a step, such that the step is moved over the slanted protrusion when the elongated case is pushed towards a rear side of the body to separate the elongated case from the body.

31. The bin of claim 26, wherein the partition is formed at a lower end thereof with a bottom insertion portion and at an upper end thereof with a partition groove, into which the bottom insertion portion is inserted, to allow two or more partitions to be detachably coupled to each other.

32. The bin of claim 22, further comprising: a partition detachably inserted into the bin to divide a space of the bin, the partition comprising an identification unit that has information of the medicines received in the bin.

33. The bin of claim 22, further comprising: an identification unit that is provided to the bin placed on each of the shelves and has identification information for distinguishing one bin from another.

34. The bin of claim 33, wherein the identification unit comprises a barcode.

35. The bin of claim 34, wherein the barcode is attached to an upper surface of a grip formed at a front upper end of the bin.

36. The bin of claim 33, wherein the identification unit comprises an RFID tag and the housing is provided with an RFID reader that recognizes the RFID tag provided to each of the bins longitudinally disposed on the shelf.

37. The bin of claim 33, wherein the identification unit comprises a memory chip that contains the identification information therein and a transmitter that transmits the identification information of the memory chip, and the shelf is provided at the bottom thereof with a receiver that receives the identification information from the transmitter.

38. The bin of claim 22, further comprising: a sliding assistor that facilitates forward or backward sliding of the bin when the bin is pulled from or inserted into the shelf.

39. A medicine management apparatus for placing and managing medicines on a plurality of shelves, comprising:
a plurality of shelves rotatably coupled to a vertically disposed circular rotary carousel; and
a plurality of bins seated on the shelves and having a box-shaped body open at an upper side thereof to accommodate medicines therein, each bin comprising an elongated case detachably coupled to an upper end of the body to increase a height of the bin.

40. A medicine management method for dispensing a medicine from a medicine management apparatus for placing and managing medicines on a plurality of shelves, comprising:
resorting medicine information of prescription data having information of medicines to be dispensed, according to the kind of medicine, dispensing the medicines from an associated shelf according to the resorted medicine information, and sorting and discharging the dispensed medicines according to patients.

41. The method of claim 40, further comprising: receiving, by the medicine management apparatus, the prescription data from corresponding database servers of drugstores or hospitals before resorting the medicine information.

42. The method of claim 40, wherein the resorting of the medicine information is performed according to shelves that store medicines to be dispensed according to patient prescription data.

43. The method of claim 40, further comprising: moving the associated shelf, which stores the medicines to be dispensed according to the resorted prescription data, to an inlet/outlet port of the apparatus before resorting the medicine information.

44. The method of claim 43, further comprising: displaying positions and amounts of the medicines to be dispensed to the patients through a display device.

45. The method of claim 40, further comprising: checking, by a user, concordance between the prescription data and the medicines when dispensing the medicines; and storing a dispensed amount of the medicines through an input/output unit of the apparatus.

46. The method of claim 45, further comprising: outputting a label printed with information of the dispensed medicines, and attaching the label to a container or a cart having a plurality of compartments for accommodating the medicines.

47. A medicine management apparatus for placing and managing medicines on a plurality of shelves, comprising:
a cart having a plurality of compartments partitioned from each other to sort and discharge medicines, which have been dispensed according to the kind of medicine from the shelves, according to patients.

48. The apparatus of claim 47, wherein a body of the apparatus and the cart exchange information with each other via wired or wireless communication.

49. The apparatus of claim 47, wherein each of the compartments in the cart is provided with a display device that displays information of a medicine received in each of the compartments through exchange of the information with the body of the apparatus or by direct input of the information by a user.

50. The apparatus of claim 47, wherein each of the compartments is provided with an inspection tester that compares information of the medicine actually placed in the corresponding compartment with information of a proper medicine to be placed in the corresponding compartment to allow a user to confirm whether the dispensed medicine is accurately placed in the corresponding compartment.

51. The apparatus of claim 47, wherein the cart is provided with a termination button that allows a subsequent operation to be continued through reception and transmission of subsequent prescription data by informing the apparatus of completion of placement of medicines in the respective compartments according to certain prescription data.

52. A medicine management method for dispensing and delivering medicines from a medicine depository to patients, comprising:
aligning medicine information of prescription data having information of medicines to be dispensed, according to the kind of medicine and patients;
dispensing the medicines of the medicine information aligned according to the kind of medicine from the medicine depository; and
inputting the dispensed medicines into a cart having a plurality of compartments.

53. The method of claim 52, wherein the medicine depository and the cart exchange information with each other via wired or wireless communication.

54. The method of claim 52, wherein the aligned medicine information according to the kind of medicine is transferred to one of a printer, a PDA and an embedded PC, and a user confirms the medicine information though one of a printout from the printer, a display window of the PDA and a display window of the embedded PC.

55. The method of claim 52, wherein the printout of the printer contains a barcode and the user attaches the printout to a corresponding compartment in the cart.

56. The method of claim 52, wherein inputting the dispensed medicines comprises inputting information of the dispensed medicines to the cart, displaying a corresponding compartment to which the dispensed medicines will be placed, and placing the dispensed medicines in the displayed compartment.

57. The method of claim 56, wherein, if there are two or more of the same kind of medicines to be placed in a single compartment, inputting the dispensed medicines is repeated corresponding to the number of the same kind of medicines to be placed in the compartment, the inputting the dispensed medicines comprising inputting information of the dispensed medicines to the cart, displaying a corresponding compartment in which the dispensed medicines will be placed, and placing the dispensed medicines in the displayed compartment.

58. The method of claim 52, wherein, when placement of the medicines in the compartments for all of the patients is completed, the dispensing the medicines from the medicine depository and the inputting the dispensed medicines into the cart are repeated for other medicines.

59. The method of claim 52, further comprising: checking the medicines placed in each of the compartments of the cart according to the patients to confirm whether all of the dispensed medicines are properly placed in the compartments according to the kind of medicine.

60. A cart for dispensing and delivering medicines from a medicine depository to patients, comprising:
a plurality of compartments that accommodate medicines according to the patients, the medicines being managed to be delivered to patients by the medicine management method of claim 52.

61. The cart of claim 60, further comprising: a wired or wireless communication unit for exchanging information with the medicine depository.

62. The cart of claim 60, further comprising: a display device that displays information of a medicine received in each of the compartments through exchange of the information with the medicine depository or by direct input of the information by a user.

63. The cart of claim 62, wherein the display device comprises a lamp provided to each of the compartments to display a target compartment for a certain medicine based on information identified by an information input unit, and an LCD window for displaying information of the certain medicine input by the information input unit.

64. The cart of claim 60, wherein the compartments comprise bag-type or tray-type compartments.
